(19) United States
(12) Patent Application Publication
(10) Pub. No.: US 2025/0149423 A1
(43) Pub. Date: May 8, 2025

(54) COMPOSITE COMPONENT DEVICE AND METHOD FOR MANUFACTURING THE SAME

(71) Applicant: Murata Manufacturing Co., Ltd., Kyoto-fu (JP)

(72) Inventor: Tatsuya FUNAKI, Nagaokakyo-shi (JP)

(73) Assignee: Murata Manufacturing Co., Ltd., Kyoto-fu (JP)

(21) Appl. No.: 19/018,263

(22) Filed: Jan. 13, 2025

Related U.S. Application Data
(63) Continuation of application No. PCT/JP2023/015137, filed on Apr. 14, 2023.

(30) Foreign Application Priority Data
Aug. 1, 2022 (JP) 2022-122856

(51) Int. Cl. H01L 23/498; H01L 21/304; H01L 21/683; H01L 21/768; H01L 23/48

(52) U.S. Cl. CPC H01L 23/49822; H01L 21/3043; H01L 21/6835; H01L 21/76898; H01L 23/481; H01L 23/49838; H01L 2221/68345

(57) ABSTRACT

A composite component device including two or more composite component layers having an electronic component layer and a rewiring layer on the electronic component layer. The two or more composite component layers are laminated in a thickness direction such that the electronic component layer and the rewiring layer are alternately disposed, and the electronic component layer has one or more electronic components having an electronic component main body having a first surface perpendicular to the thickness direction and a second surface opposed to the first surface; and component electrodes on the first surface. The component electrode of the one or more electronic components is electrically connected to the rewiring layer, and an electronic component layer in a composite component layer adjacent to the rewiring layer of two or more composite component layers has an electronic component layer through-via electrically connected to the rewiring layer of another composite component layer.

### CROSS-REFERENCE TO RELATED APPLICATIONS

This application claims benefit of priority to International Patent Application No. PCT/JP2023/015137, filed Apr. 14, 2023, and to Japanese Patent Application No. 2022-122856, filed Aug. 1, 2022, the entire contents of each are incorporated herein by reference.

### BACKGROUND

### Technical Field

The present disclosure relates to a composite component device and a method for manufacturing the same.

### Background Art

Conventionally, as a package in which a plurality of electronic components are combined, for example, there is an apparatus described in FIG. 4F of Japanese Patent Application Laid-Open No. 2019-125779. This apparatus (400F) includes a rewiring layer (306), a first mold layer (316) disposed on the rewiring layer (306), and a second mold layer (326) disposed on the first mold layer (316). The die (318, 320) sealed in the second mold layer (326) is connected to the bridge die (310) sealed in the first mold layer (316) with the electrical connection portion (312) interposed therebetween, and is connected to the rewiring layer (306) with the electrical connection portion (314) interposed therebetween.

### SUMMARY

The present inventor has found that the apparatus as described above has the following problem. That is, the die, the bridge die, and the wiring layer are connected with a ball (bump) interposed therebetween. For this reason, the connection resistance is relatively high, and there is a risk of lowering the reliability due to cracking or the like of the bump. Further, there is a risk of forming a space in the apparatus due to the bump used during manufacturing and hindering height reduction.

Therefore, the present disclosure provides a composite component device capable of improving reliability and reducing the height.

The present inventor has intensively investigated, and has found that in a composite component device including two or more composite component layers having an electronic component layer and a rewiring layer provided in the electronic component layer, electrical connection between one or more electronic components and the rewiring layer and electrical connection between two or more composite component layers are achieved without using solder bumps. On the basis of such technical knowledge, the present disclosure has been conceived in which a component electrode is electrically connected to a rewiring layer, and composite component layers are electrically connected each other to an electronic component layer through-via. That is, the present disclosure includes the following embodiments.

The composite component device according to an aspect of the present disclosure is a composite component device including two or more composite component layers having an electronic component layer and a rewiring layer provided on the electronic component layer. The two or more composite component layers are laminated in a thickness direction such that the electronic component layer and the rewiring layer are alternately disposed. Also, the electronic component layer has one or more electronic components having: an electronic component main body having a first surface perpendicular to the thickness direction and a second surface opposed to the first surface; and a plurality of component electrodes disposed on the first surface. In addition, the component electrode of the one or more electronic components is electrically connected to the rewiring layer, and an electronic component layer in a composite component layer adjacent to the rewiring layer of another composite component layer of the two or more composite component layers further has an electronic component layer through-via electrically connected to the rewiring layer of the another composite component layer.

According to the above embodiment, the component electrode is electrically connected to the rewiring layer, and the composite component layers are electrically connected each other to the electronic component layer through-via. Thereby, in the composite component device, the wiring length (in particular, the length of the via wiring in the thickness direction of the composite component device) can be shortened as compared with a case of electrical connection using the bump (for example, solder bumps), and thus the connection resistance can be reduced, and the reliability can be enhanced. As a result, in the composite component device, the space caused by the bump between the composite component layers can be eliminated and the height can be reduced as compared with the case of electrical connection using the bump.

Therefore, a composite component device according to one embodiment of the present disclosure is capable of improving reliability and reducing the height.

### BRIEF EXPLANATION OF DRAWINGS

FIG. 1 is a sectional view showing a composite component according to a first embodiment;

FIG. 2 is an enlarged view of a portion A in FIG. 1;

FIG. 3 is an enlarged view of a portion B in FIG. 1;

FIG. 4A is an explanatory view showing a method for manufacturing the composite component device according to the first embodiment;

FIG. 4B is an explanatory view showing a method for manufacturing the composite component device according to the first embodiment;

FIG. 4C is an explanatory view showing a method for manufacturing the composite component device according to the first embodiment;

FIG. 4D is an explanatory view showing a method for manufacturing the composite component device according to the first embodiment;

FIG. 4E is an explanatory view showing a method for manufacturing the composite component device according to the first embodiment;

FIG. 4F is an explanatory view showing a method for manufacturing the composite component device according to the first embodiment;

FIG. 4G is an explanatory view showing a method for manufacturing the composite component device according to the first embodiment;

FIG. 4H is an explanatory view showing a method for manufacturing the composite component device according to the first embodiment;

FIG. 4I is an explanatory view showing a method for manufacturing the composite component device according to the first embodiment;

FIG. 4J is an explanatory view showing a method for manufacturing the composite component device according to the first embodiment;

FIG. 4K is an explanatory view showing a method for manufacturing the composite component device according to the first embodiment;

FIG. 4L is an explanatory view showing a method for manufacturing the composite component device according to the first embodiment;

FIG. 4M is an explanatory view showing a method for manufacturing the composite component device according to the first embodiment;

FIG. 4N is an explanatory view showing a method for manufacturing the composite component device according to the first embodiment;

FIG. 4O is an explanatory view showing a method for manufacturing the composite component device according to the first embodiment;

FIG. 4P is an explanatory view showing a method for manufacturing the composite component device according to the first embodiment;

FIG. 4Q is an explanatory view showing a method for manufacturing the composite component device according to the first embodiment;

FIG. 4R is an explanatory view showing a method for manufacturing the composite component device according to the first embodiment;

FIG. 4S is an explanatory view showing a method for manufacturing the composite component device according to the first embodiment;

FIG. 4T is an explanatory view showing a method for manufacturing the composite component device according to the first embodiment;

FIG. 4U is an explanatory view showing a method for manufacturing the composite component device according to the first embodiment;

FIG. 4V is an explanatory view showing a method for manufacturing the composite component device according to the first embodiment;

FIG. 5 is a sectional view showing a composite component according to the second embodiment;

FIG. 6A is an explanatory view showing a method for manufacturing a composite component device according to the second embodiment;

FIG. 6B is an explanatory view showing a method for manufacturing a composite component device according to the second embodiment;

FIG. 6C is an explanatory view showing a method for manufacturing a composite component device according to the second embodiment;

FIG. 6D is an explanatory view showing a method for manufacturing a composite component device according to the second embodiment;

FIG. 6E is an explanatory view showing a method for manufacturing a composite component device according to the second embodiment;

FIG. 6F is an explanatory view showing a method for manufacturing a composite component device according to the second embodiment;

FIG. 6G is an explanatory view showing a method for manufacturing a composite component device according to the second embodiment;

FIG. 6H is an explanatory view showing a method for manufacturing a composite component device according to the second embodiment;

FIG. 6I is an explanatory view showing the method for manufacturing the composite component device according to the second embodiment;

FIG. 6J is an explanatory view showing a method for manufacturing the composite component device according to the second embodiment;

FIG. 6K is an explanatory view showing a method for manufacturing the composite component device according to the second embodiment;

FIG. 6L is an explanatory view showing a method for manufacturing the composite component device according to the second embodiment;

FIG. 6M is an explanatory view showing a method for manufacturing the composite component device according to the second embodiment;

FIG. 6N is an explanatory view showing a method for manufacturing the composite component device according to the second embodiment;

FIG. 6O is an explanatory view showing a method for manufacturing the composite component device according to the second embodiment;

FIG. 7 is a sectional view showing a composite component according to a third embodiment;

FIG. 8 is an enlarged view of a portion D in FIG. 7;

FIG. 9A is an explanatory view showing a method for manufacturing a composite component device according to the third embodiment;

FIG. 9B is an explanatory view showing a method for manufacturing a composite component device according to the third embodiment;

FIG. 9C is an explanatory view showing a method for manufacturing a composite component device according to the third embodiment;

FIG. 9D is an explanatory view showing a method for manufacturing a composite component device according to the third embodiment;

FIG. 9E is an explanatory view showing a method for manufacturing a composite component device according to the third embodiment;

FIG. 9F is an explanatory view showing a method for manufacturing a composite component device according to the third embodiment;

FIG. 9G is an explanatory view showing a method for manufacturing a composite component device according to the third embodiment;

FIG. 9H is an explanatory view showing a method for manufacturing a composite component device according to the third embodiment;

FIG. 9I is an explanatory view showing the method for manufacturing the composite component device according to the third embodiment;

FIG. 9J is an explanatory view showing a method for manufacturing the composite component device according to the third embodiment;

FIG. 10A is an explanatory view showing a method for manufacturing a composite component device according to the first embodiment; and

FIG. 10B is an explanatory view showing a method for manufacturing a composite component device according to the first embodiment.

### DETAILED DESCRIPTION

Hereinafter, the composite component device and the method for manufacturing the same according to one aspect of the present disclosure will be described in detail by illustrated embodiments. The drawings include some schematic drawings and do not reflect actual dimensions or ratios in some cases. In addition, the dimensions (more specifically, the thickness and the like) of the components in the composite component device were measured based on scanning electron microscope (SEM) images taken with a SEM. The dimension was obtained from an average value of a plurality of measurement numbers (measurement numbers n≥3).

The various numerical ranges referred to herein are intended to include the lower and upper numerical values (namely, the upper limit value and the lower limit value) themselves, unless otherwise stated, such as “less than”, “greater than”, and “smaller than”. That is, for example, when a numerical range of 80 to 120 μm is taken as an example, the numerical range of 80 to 120 μm is interpreted as including the lower limit value “80 μm” and also including the upper limit value “120 μm”.

### First Embodiment: Composite Component Device

The composite component device according to the first embodiment includes two or more composite component layers. In the present embodiment, a composite component device including three composite component layers will be described as an example.

The composite component device according to the first embodiment is a composite component device including two or more composite component layers having an electronic component layer and a rewiring layer provided on the electronic component layer. Two or more composite component layers are laminated in a thickness direction such that the electronic component layer and the rewiring layer are alternately disposed. Also, the electronic component layer has one or more electronic components having: an electronic component main body having a first surface perpendicular to the thickness direction and a second surface opposed to the first surface; and a plurality of component electrodes disposed on the first surface. The component electrode of the one or more electronic components is electrically connected to the rewiring layer, and an electronic component layer in a composite component layer adjacent to the rewiring layer of another composite component layer of two or more composite component layers further has an electronic component layer through-via electrically connected to the rewiring layer of another composite component layer.

### Mechanism of Action

The composite component device according to the first embodiment can improve reliability and reduce height. Although not bound by a specific theory, the reason is presumed as follows.

In the composite component device according to the first embodiment, the component electrode is electrically connected to the rewiring layer, and the composite component layers are electrically connected each other to the electronic component layer through-via. Thereby, in the composite component device, the wiring length (in particular, the length of the via wiring in the thickness direction of the composite component device) can be shortened as compared with a case of electrical connection using the bump (for example, solder bumps), and thus the connection resistance can be reduced, and the reliability can be enhanced. As a result, in the composite component device, the space caused by the bump between the composite component layers can be eliminated and the height can be reduced as compared with the case of electrical connection using the bump.

### Configuration of Composite Component Device

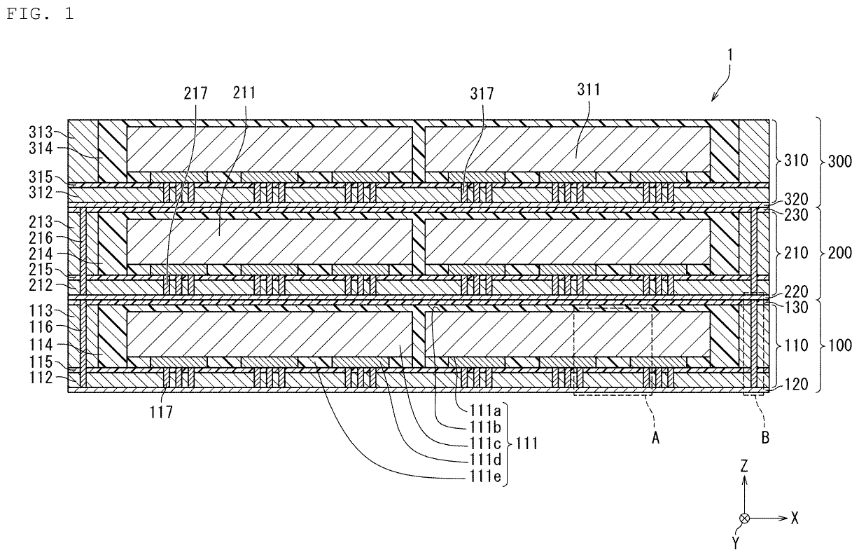

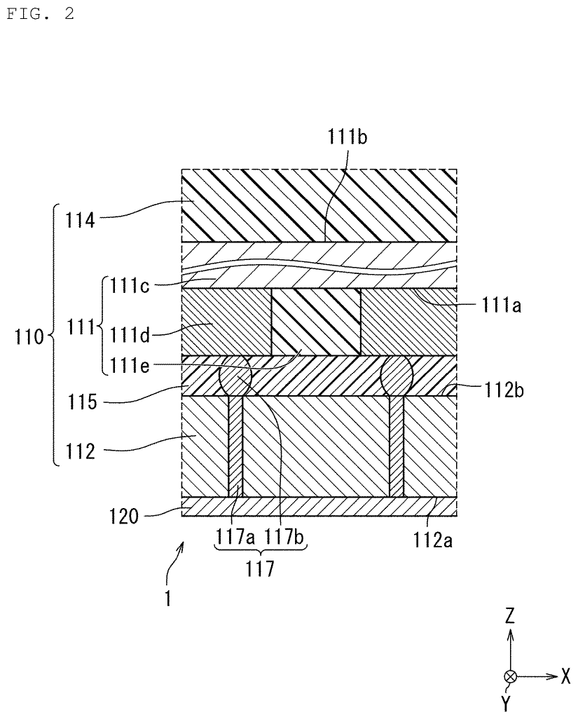

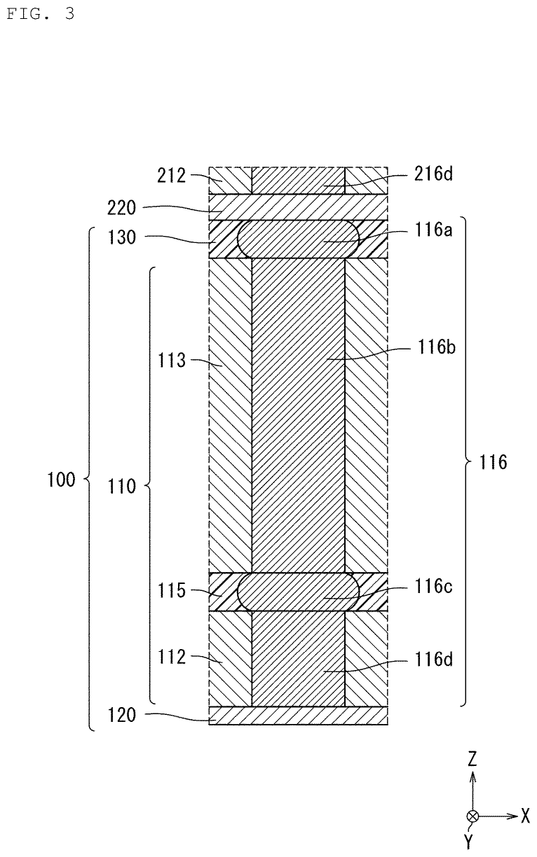

A configuration of the composite component device according to the first embodiment will be described with reference to FIGS. 1, 2, and 3. FIG. 1 is a view schematically illustrating a section of the composite component device according to a first embodiment of the present disclosure. FIG. 2 is an enlarged view of a portion A in FIG. 1. FIG. 3 is an enlarged view of a portion B in FIG. 1.

As illustrated in FIG. 1, a composite component device 1 includes three composite component layers 100, 200, and 300. In FIG. 1, a direction parallel to the thickness of the composite component device 1 is defined as a Z direction, a forward Z direction is defined as an upper side, and an inverse Z direction is defined as a lower side. In the section of the composite component device 1 shown in FIG. 1, a direction perpendicular to the Z direction is defined as an X direction. A direction perpendicular to the section of the composite component device 1 illustrated in FIG. 1 is defined as a Y direction.

### Composite Component Layer

The composite component layers 100, 200, and 300 include electronic component layers 110, 210, and 310 and rewiring layers 120, 220, and 320 provided in the electronic component layers 110, 210, and 310, respectively. The three composite component layers 100, 200, and 300 are laminated in the thickness direction such that the electronic component layers 110, 210, and 310 and the rewiring layers 120, 220, and 320 are alternately disposed. When the composite component layer is connected to the rewiring layer of another composite component layer, the composite component layer further includes an interlayer adhesive layer. Specifically, the composite component layers 100 and 200 further include interlayer adhesive layers 130 and 230.

The configuration of the second and third composite component layers 200 and 300 is substantially the same as the configuration of the first composite component layer 100, and thus the first composite component layer 100 will be described below as an example. However, the second and third composite component layers 200 and 300 may be referred to at points different from the first composite component layer 100. The third composite component layer 300 differs from the first and second composite component layers 100 and 200 from the viewpoint of having no interlayer adhesive layer and no composite component layer through-via.

### Electronic Component Layer

The lower surface of a first electronic component layer 110 adheres (is joined) to a first rewiring layer 120, and the upper surface thereof adheres to a second rewiring layer 220 of a second composite component layer 200 with a first interlayer adhesive layer (first composite component adhesive layer) 130 interposed therebetween. Herein, as described later, the first rewiring layer 120 and the second rewiring layer 220 are, for example, sheets or substrates of multilayer wiring layers, and have, for example, a wiring (conductive wiring) 120b and a dielectric film 120a containing an inorganic material (inorganic insulating material). The first electronic component layer 110 has one or more first electronic components 111 and first electronic component layer through-vias 116, and further has a first Si base layer 112, a first side wall portion 113, a first resin sealing portion 114, a first electronic component adhesive layer 115, and a first Si through-via 117.

### Electronic Component

One or more first electronic components 111 are disposed in the first composite component layer 100. One or more first electronic components 111 have: a first electronic component main body 111c having a first surface 111a perpendicular to the thickness direction and a second surface 111b opposed to the first surface 111a (a first surface 111a and a second surface 111b opposed to each other); a plurality of first component electrodes 111d disposed on the first surface 111a; and a first insulating portion 111e disposed between the plurality of first component electrodes 111d. The first electronic component 111 is supported by the first Si base layer 112 with the first electronic component adhesive layer 115 interposed therebetween. The first electronic component 111 is sealed in the first composite component layer 100 by a first resin sealing portion 114. The first component electrode 111d of the first electronic component 111 is electrically connected to the first rewiring layer 120 with the first Si through-via 117 interposed therebetween. When there is a plurality of one or more first electronic components 111, the first electronic components 111 may be of the same type or different types. The thickness of the first electronic component 111 is, for example, 80 to 120 μm.

One or more first electronic components 111 (specifically, the two first electronic components 111) are disposed in the first composite component layer 100 such that all of the first surfaces 111a are located on the first rewiring layer 120 side with respect to the second surface 111b. As for the second and third composite component layers 200 and 300, similarly to the disposition direction of the one or more first electronic components 111, the one or more second and third electronic components 211 and 311 are also disposed in the second and third composite component layers 200 and 300 such that all of the first surfaces 211a and 311a thereof are located on the sides of the second and third rewiring layers 220 and 320 with respect to the second surfaces 211b and 311b. These one or more electronic components 111, 211, and 311 are connected to the rewiring layer 120, 220, and 320, respectively. As described above, the composite component device 1 has simple wiring, and thus not only two layers but also three or more layers of composite component layers can be laminated.

The one or more first electronic components 111 are, for example, electronic components in which one or more elements are integrated in a substance similar to the substance including the first Si base layer 112. The first electronic component 111 is, for example, an active component (more specifically, CPU, GPU, LSI, and the like) and a passive component (more specifically, a capacitor, a resistor, an inductor, and the like).

The first electronic component main body 111c includes, for example, a ceramic or semiconductor material (more specifically, silicon or the like).

The first component electrode 111d is made of a conductive material such as Cu, Ni, Sn, Al, and an alloy thereof. Among these, the conductive material is preferably the same material as the first Si through-via 117. The thickness of the first component electrode 111d is, for example, 1 μm to 30 μm, and preferably 5 μm or less. The first component electrode 111d can be thinned to a thickness of 1 to 5 μm. The thickness of the first component electrode 111d can be, for example, ¼ to ⅙ fold of the thickness of the first electronic component main body 111c.

The first insulating portion 111e functions as a layer for electrical insulation between the first component electrodes 111d. The thickness of the first insulating portion 111e is, for example, 1 to 30 μm, and preferably 5 μm or less. The first component electrode 111d can be thinned to a thickness of 1 to 5 μm. The thickness of the first insulating portion 111e can be set to, for example, ¼ to ⅙ fold of the thickness of the first electronic component main body 111c. The thickness of the first insulating portion 111e may be the same as that of the first component electrode 111d, and in this case, the lower surface of the first insulating portion 111e and the lower surface of the first component electrode 111d are flush with each other.

### Si Base Layer

The first Si base layer 112 has a first main surface 112a and a second main surface 112b opposed to each other. The first Si base layer 112 supports one or more first electronic components 111 with a first electronic component adhesive layer 115 interposed therebetween on the second main surface 112b, and is connected to the first rewiring layer 120 on the first main surface 112a. The first Si base layer 112 substantially includes Si. Herein, substantially including Si means that the subject member contains Si at a ratio of 99% by mass or more.

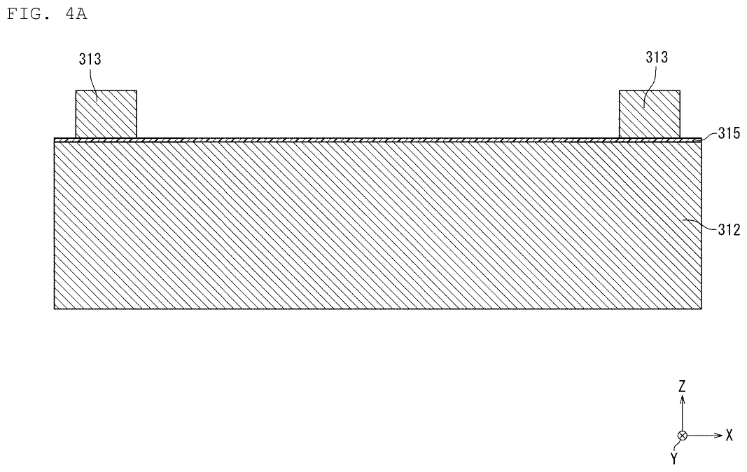

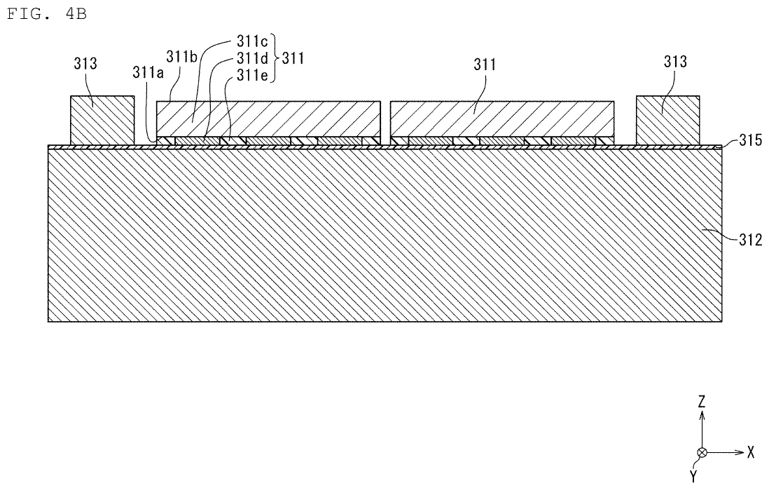

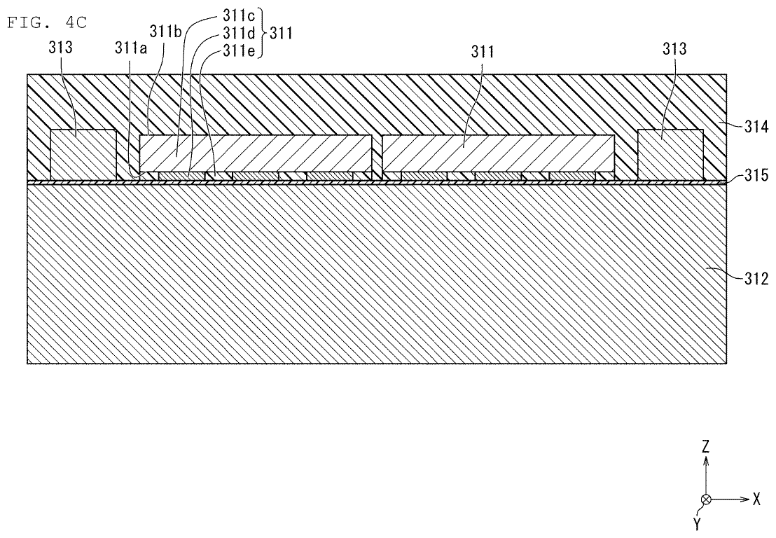

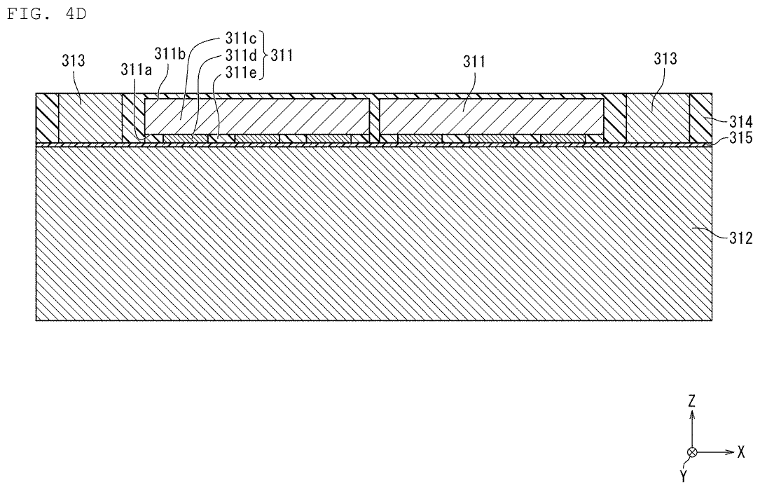

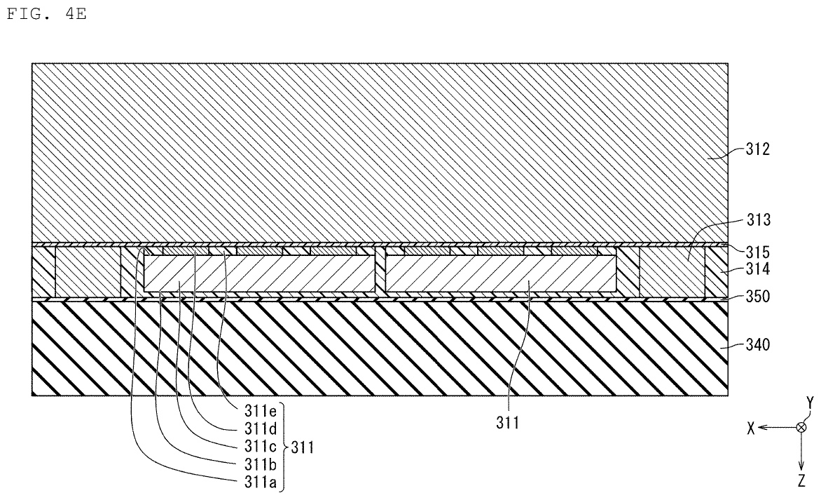

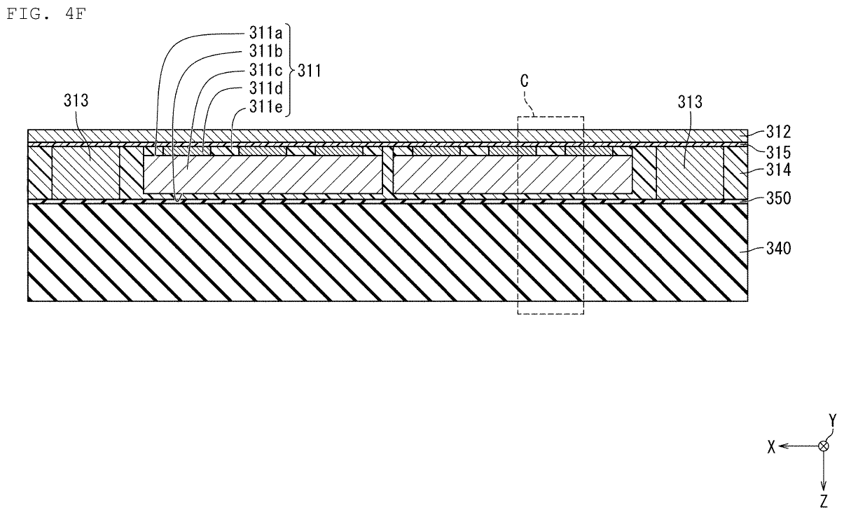

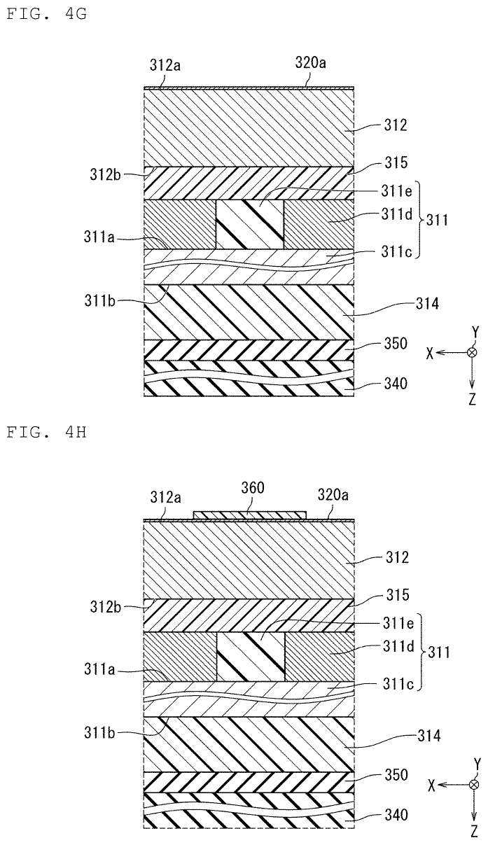

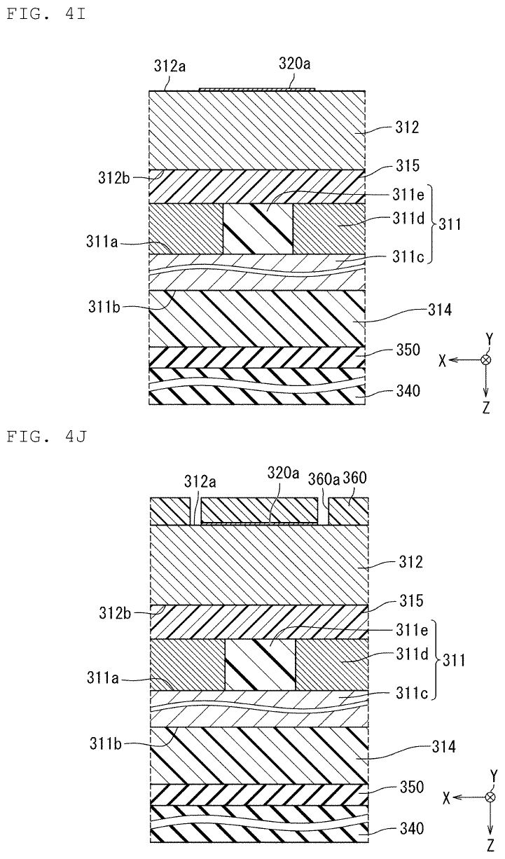

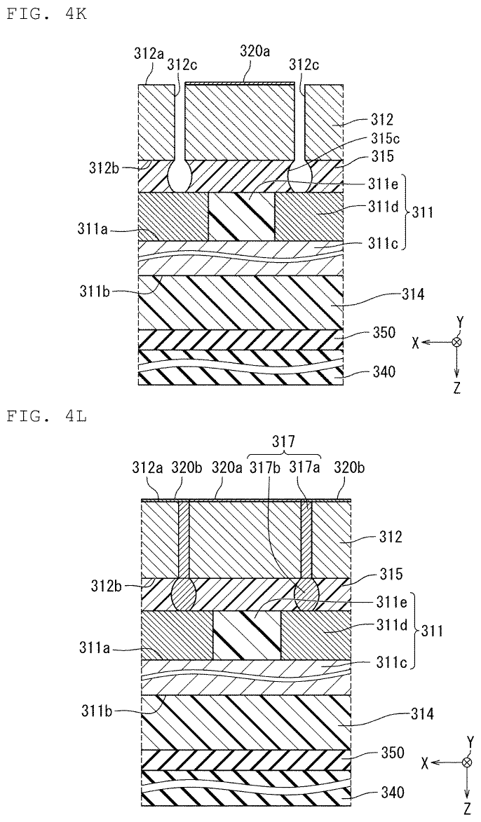

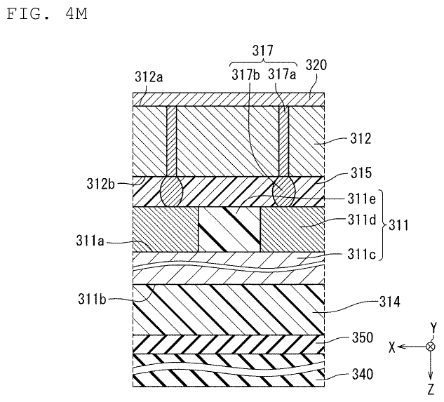

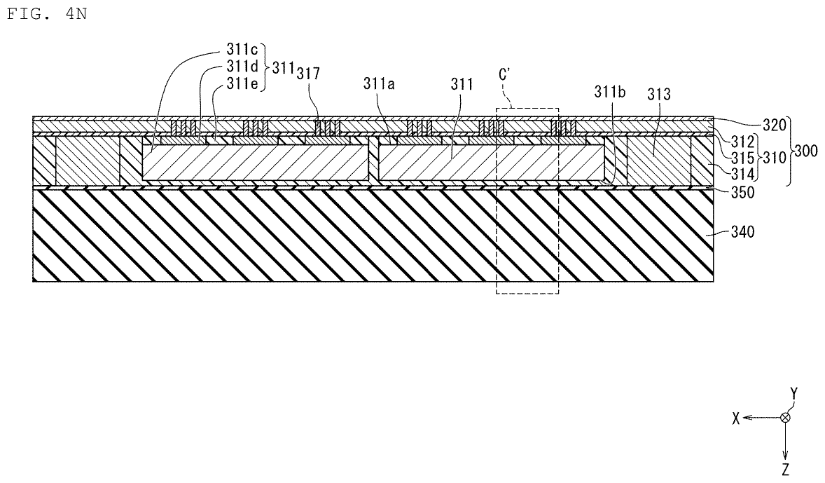

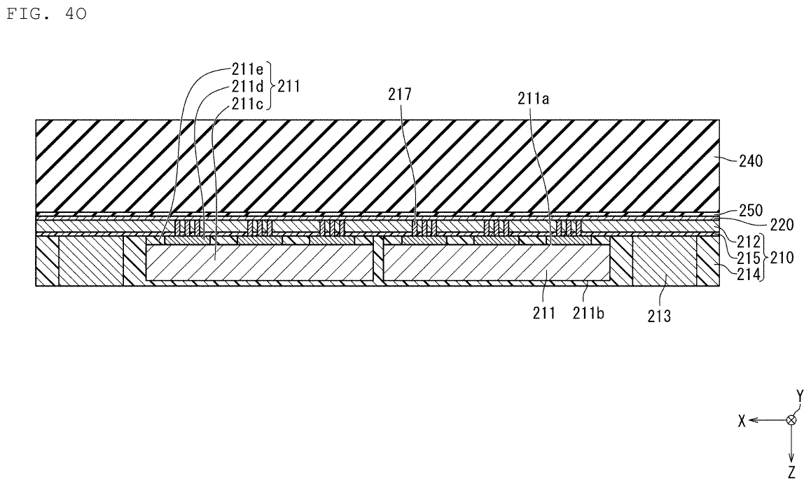

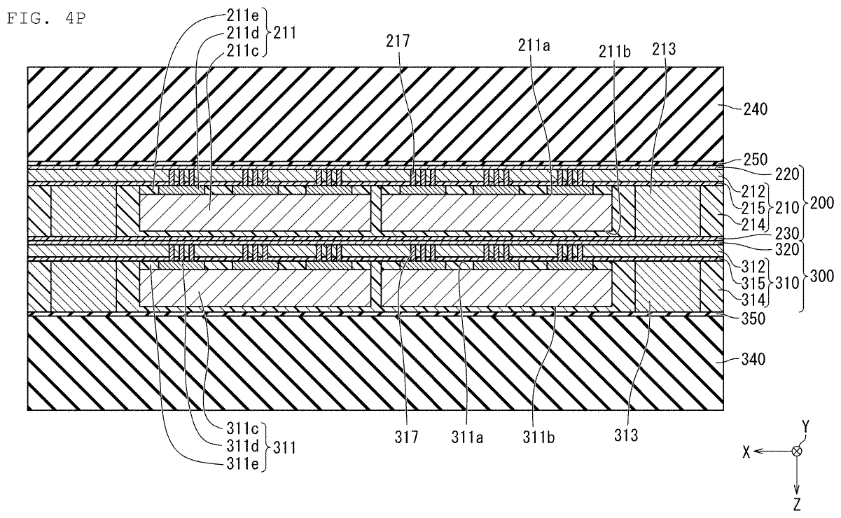

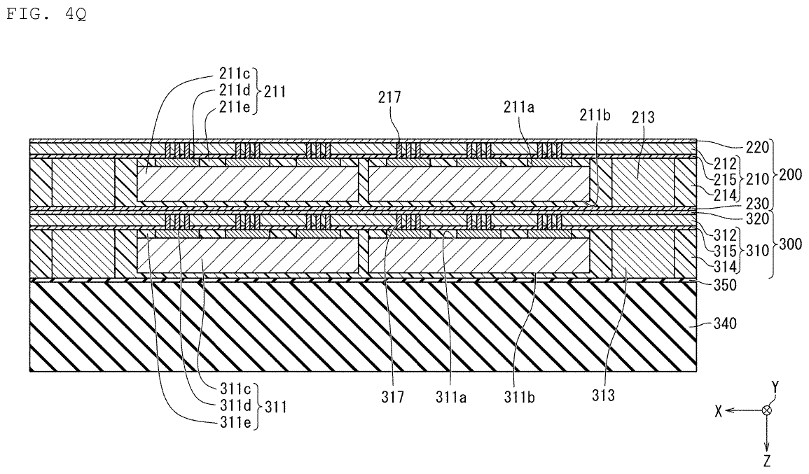

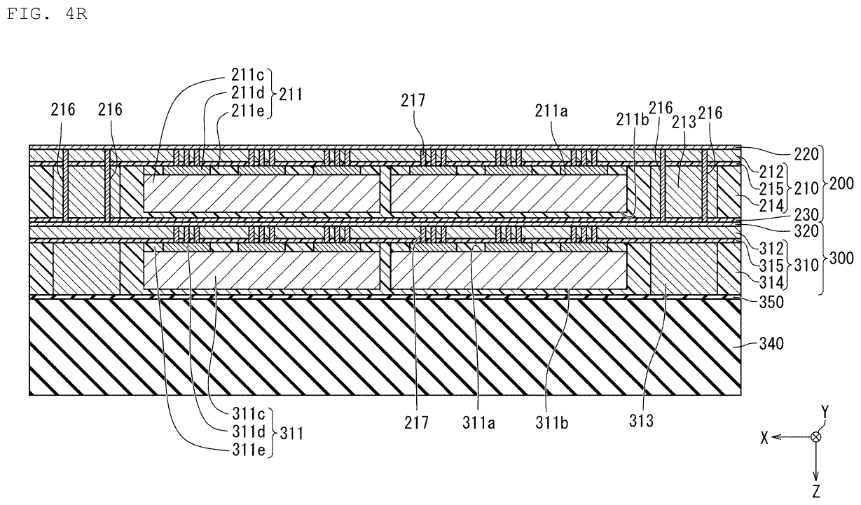

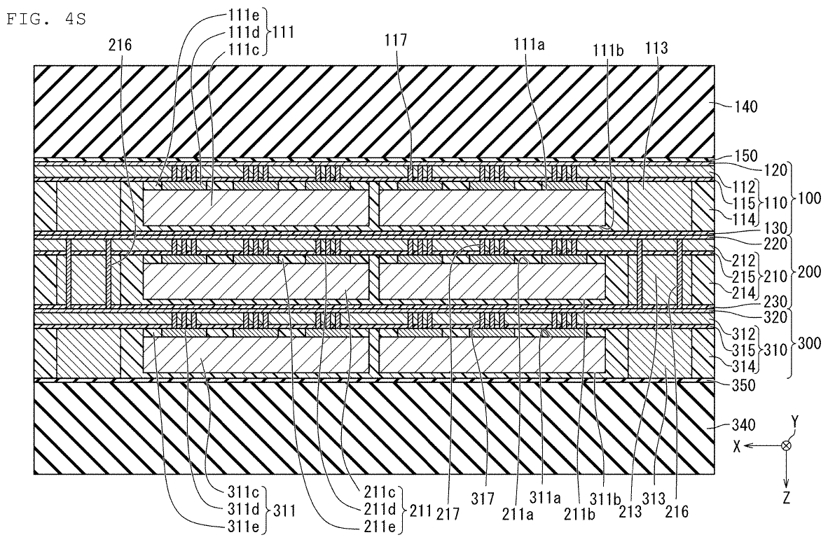

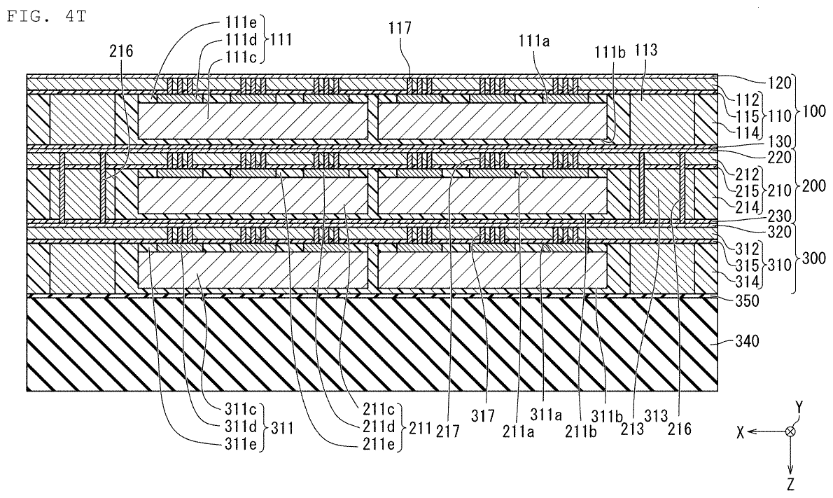

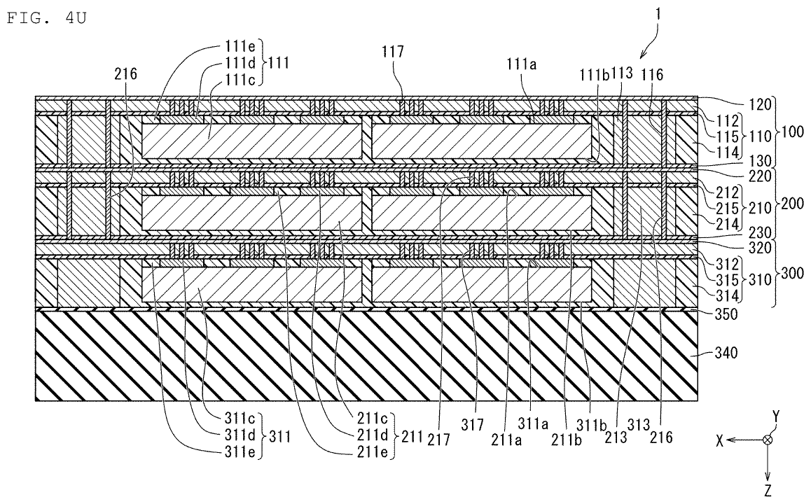

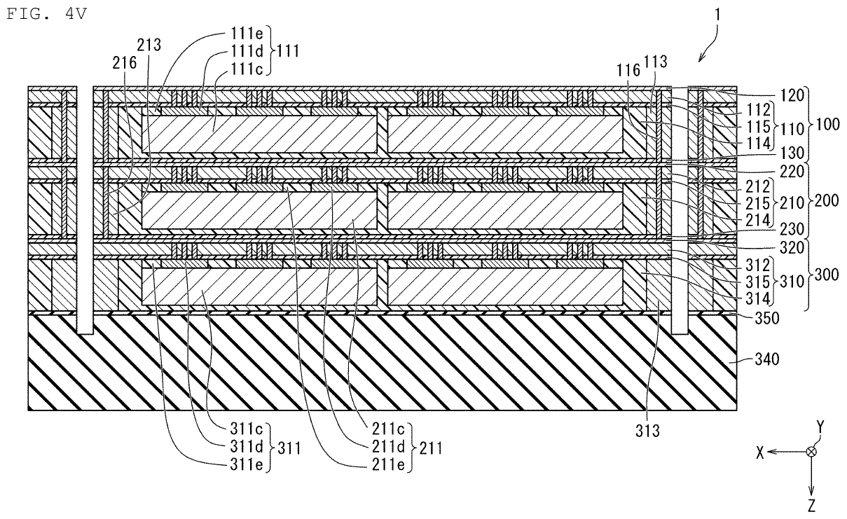

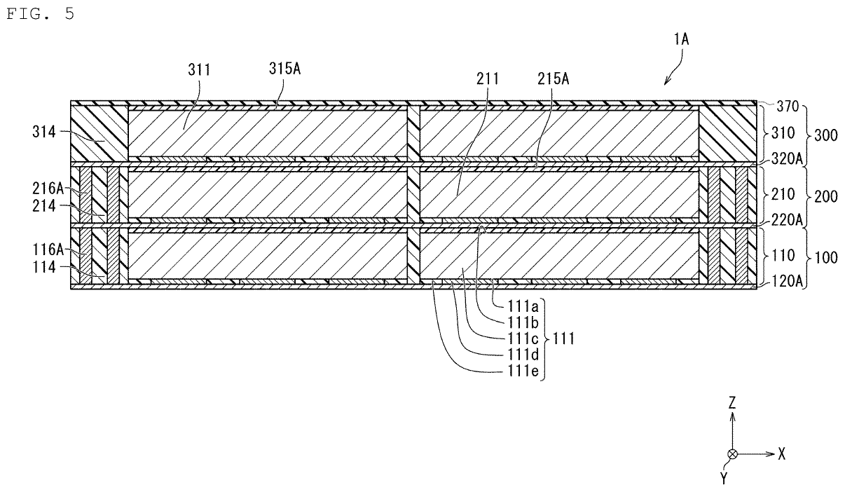

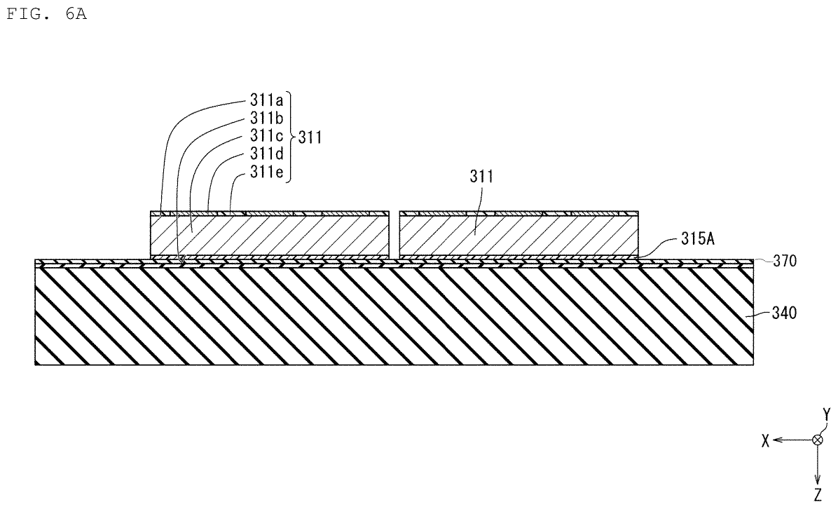

The thickness of the first Si base layer 112 is, for example, 150 μm or less, preferably 50 μm or less, and more preferably 30 μm or less. The reason why the thickness of the first Si base layer 112 can be made extremely thin in this manner is that in the method for manufacturing the composite component device 1 described later, the first Si support 140 is attached to the first Si base layer 112 to reinforce the strength, and thus if the first Si base layer 112 is ground to make it thinner, damage (such as cracks) to the first Si base layer 112 due to insufficient strength is unlikely to occur (refer to FIG. 4E and 4F). The reinforcement of the strength by the first Si support 140 allows production of the composite component device 1. The thickness of the first Si base layer 112 can be made extremely thinner than that of the conventional one, thus allowing to shorten the length of the via wiring (that is, the first Si through-via 117) electrically connecting the first component electrode 111d of one or more electronic components 111 to the first rewiring layer 120. This reduces the parasitic impedance caused by the via wiring, and can improve the electrical characteristics of the electronic device using the composite component device 1.

### Side Wall Portion

As illustrated in FIG. 3 in addition to FIG. 1, the first side wall portion 113 is disposed on the second main surface 112b of the first Si base layer 112 so as to surround one or more first electronic components 111. The first side wall portion 113 is disposed at both end portions of the first composite component layer 100 so as to surround the entire of one or more electronic components 111. The first electronic component layer through-via 116 penetrates the inside of the first side wall portion 113. The first side wall portion 113 has a substantially rectangular shape in a sectional view, is connected to the second rewiring layer 220 of the second composite component layer 200 with the first interlayer adhesive layer 130 interposed therebetween on an upper surface thereof, and adheres to the first Si base layer 112 with the first electronic component adhesive layer 115 interposed therebetween on a lower surface thereof. The thickness of the first side wall portion 113 is, for example, 90 to 130 μm. The first side wall portion 113 substantially includes Si, for example.

### Resin Sealing Portion

The first resin sealing portion 114 seals one or more first electronic components 111. The resin sealing portion 114 contains a resin (for example, epoxy resin), and a plurality of (two or more) first electronic components 111 can be integrated with the resin. The plurality of first electronic components 111 can be integrated with the resin, and thus when two or more first electronic components 111 have different dimensions and shapes with each other, two or more first electronic components 111 can be disposed in the first electronic component layer 110. Thereby, design with a high degree of freedom becomes possible, and two or more first electronic components 111 can be combined according to the application. For example, the composite component device 1 can incorporate different types of first electronic components 111.

### Electronic Component Adhesive Layer

The first electronic component adhesive layer 115 causes one or more first electronic components 111 to adhere to the second main surface 112b of the first Si base layer 112. In the present description, the thickness of first electronic component adhesive layer 115 refers to the thickness in the Z direction from the lower surface of the first component electrode 111d to the second main surface 112b of the first Si base layer 112. The thickness of the first electronic component adhesive layer 115 is, for example, 4 to 6 μm.

### Electronic Component Layer Through-Via

An electronic component layer in a composite component layer adjacent to a rewiring layer of another composite component layer among the two or more composite component layers further has an electronic component layer through-via electrically connecting to the rewiring layer of another composite component layer. That is, when a composite component layer adheres to a rewiring layer of another composite component layer, the composite component layer further has an electronic component layer through-via electrically connecting to the rewiring layer of the another composite component layer.

For example, the first electronic component layer 110 in the first composite component layer 100 adjacent to the second rewiring layer 220 of the second composite component layer 200 further has a first electronic component layer through-via 116 electrically connecting to the second rewiring layer 220 of the second composite component layer 200. That is, the first composite component layer 100 is connected to the second rewiring layer 220 of another second composite component layer 200, and thus the first electronic component layer 110 further has the first electronic component layer through-via 116 electrically connecting to the second rewiring layer 220 of the second composite component layer 200. The second composite component layer 200 is connected to the third rewiring layer 320 of the third composite component layer 300, and thus the second electronic component layer 210 further has a second electronic component layer through-via 216 electrically connecting to a third rewiring layer 320 of a third composite component layer 300. On the other hand, the third composite component layer 300 is not connected to a rewiring layer of another composite component layer, and thus the third composite component layer 300 does not have an electronic component layer through-via.

The first electronic component layer through-via 116 is through the first electronic component layer 110 in the Z direction (more specifically, is through the first side wall portion 113, the first electronic component adhesive layer 115, and the first Si base layer 112 in the Z direction), and also is through the first interlayer adhesive layer 130. The first electronic component layer through-via 116 has an adhesive layer conductive via 116a penetrating the first interlayer adhesive layer 130, a sidewall through-via 116b penetrating the first side wall portion 113, a conductive via 116c penetrating the first electronic component adhesive layer 115, and a Si through-via 116d penetrating the first Si base layer 112. The adhesive layer conductive via 116a electrically connects the first electronic component layer through-via 116 and the second rewiring layer 220 of the second composite component layer 200. On a plane perpendicular to the thickness direction of the composite component device 1, a sectional area of the adhesive layer conductive via 116a (sectional area on the XY plane) is larger than a sectional area of the sidewall through-via 116b. Therefore, the first electronic component layer through-via 116 has favorable electrical connection with the second rewiring layer 220, and the connection resistance between the first and second composite component layers 100 and 200 is reduced, thereby further improving the reliability.

The first electronic component layer through-via 116 preferably substantially includes copper. Herein, substantially including copper (Cu) means that the object member contains copper at a ratio of 99% by mass or more in the present description. When the first electronic component layer through-via 116 substantially includes copper, the electrical resistance of the wiring is reduced because copper is a favorable conductive material.

### Si Through-Via

As illustrated in FIG. 2 in addition to FIG. 1, the first Si through-via 117 is through the first Si base layer 112 (and the first electronic component adhesive layer 115) to electrically connect the first component electrode 111d and the first rewiring layer 120. The first Si through-via 117 has the Si through-via main body 117a and the extending portion 117b. The Si through-via main body 117a is electrically connected to the first rewiring layer 120 and penetrates the first Si base layer 112. The extending portion 117b is electrically connected to the Si through-via main body 117a, extends from the second main surface 112b of the first Si base layer 112, is through the first electronic component adhesive layer 115, and is electrically connected to the first component electrode 111d. As described above, the via wiring electrically connecting the first component electrode 111d through the first rewiring layer 120 includes only the first Si through-via 117, and thus does not have (does not need) a bump (for example, solder bump). Therefore, the composite component device 1 according to the present embodiment can further reduce the parasitic impedance due to the via wiring. Further, this improves the electrical characteristics of the electronic device using the composite component device 1. Further, the wiring length can be shortened as compared with the related art, and thus the thickness of the composite component device 1 can be reduced, and the composite component device 1 can be reduced in size, thickness, and height. The length of the via wiring (that is, the length of the first Si through-via 117 in the laminating direction) is, for example, 3 μm to 36 μm. For reference, for example, solder bumps generally have a diameter of 100 to 150 μm.

In FIG. 2, the first Si through-via 117 is substantially linear in the laminating direction. The sectional shape of the first Si through-via 117 in the ZX plane is substantially rectangular in FIG. 2. Further, the sectional shape of the first Si through-via 117 on the XY plane is, for example, a substantially circular shape, a substantially polygonal shape, and a shape in which corners of the substantially polygonal shape are rounded.

### Rewiring Layer

The first rewiring layer 120 is formed on the first main surface 112a of the first Si base layer 112. The first rewiring layer 120 is a multilayer wiring layer. The first rewiring layer 120 has wiring (conductive wiring) 120b and a dielectric film 120a substantially including an inorganic material (inorganic insulating material).

The wiring 120b has a conductive via. The conductive via electrically connects wirings between different layers in the first rewiring layer 120. The wiring 120b includes a conductive material. The conductive material is, for example, Cu, Ag, Au, and alloys containing them, and among them, Cu is preferable. The first rewiring layer 120 can have a plurality of layers, and has, for example, two or more layers of wiring 120b and one or more layers of dielectric films 120a. The thicknesses of one layer of the wiring 120b and one layer of the dielectric film 120a including the first rewiring layer 120 are, for example, 1.5 μm to 5.0 μm. In this case, the thickness of the first rewiring layer 120 is a value (unit: μm) obtained by multiplying the thickness of one layer thereof (1.5 μm to 5.0 μm) by the total number of layers in the first rewiring layer 120.

The dielectric film 120a substantially includes an inorganic material as an insulating material (inorganic insulating material). Herein, substantially including an inorganic material means that the target member contains the inorganic material at a ratio of 99% by mass or more in the present description. Examples of the inorganic insulating material include silicon oxide (SiO₂) and silicon nitride (SiN and Si₃N₄). When the dielectric film 120a includes an inorganic insulating material, for example, the wiring width can be made about 1/10 fold of the dielectric film in the composite component device 1A according to the second embodiment. This allows further reduction in size and height of the composite component device 1. The line-and-space (L/S) of the first rewiring layer 120 including the dielectric film 120a substantially including an inorganic material is, for example, 1 μm/1 μm.

The dielectric film 120a has a thickness of, for example, 0.1 to 2 μm. The dielectric film 120a may be a multi-component film containing two or more components. The multi-component film may be a multi-layer film in which multiple layers are formed for each component. The layer structure of the multi-layer film is, for example, SiO₂ (thickness 0.25 μm)/Si₃N₄ (thickness 0.1 μm)/SiO₂ (thickness 0.25 μm)/Si₃N₄ (thickness 0.1 μm) in this order from the first Si base layer 112 side.

### Interlayer Adhesive Layer

The first interlayer adhesive layer 130 causes the first electronic component layer 110 to adhere the second rewiring layer 220 of the second composite component layer 200.

### Method for Manufacturing Composite Component Device

An example of a method for manufacturing the composite component device 1 according to the first embodiment will be described.

The method for manufacturing the composite component device 1 according to the first embodiment includes: for example, an electronic component adhesive step of causing one or more electronic components to adhere to a Si base layer such that a plurality of component electrodes of one or more electronic components contact the bottom surface portion of the Si base layer having a lattice-shaped side wall portion with the electronic component adhesive layer interposed therebetween; an electronic component sealing step of sealing one or more electronic components with resin to form a resin sealing portion; a rewiring layer forming step of forming a rewiring layer to make a composite component layer; and a laminating step of forming another composite component layer by the electronic component adhesive step, the electronic component sealing step, and the rewiring layer forming step, forming an electronic component layer through-via on the side wall portion of the another composite component layer, and laminating the another composite component layer on the composite component layer. The laminating step is performed at least once.

The method for manufacturing the composite component device 1 according to the first embodiment further includes a Si base layer thinning step of thinning the Si base layer; a through hole forming step of forming a through hole in the thinned Si base layer and the electronic component adhesive layer to expose a part of the surface of the component electrode; and a Si through-via forming step of forming a Si through-via in the through hole.

The method for manufacturing the composite component device 1 according to the first embodiment may further include a Si base layer preparing step of preparing a Si base layer; an insulating portion forming step of forming an insulating portion between component electrodes; a resin sealing portion thinning step of thinning a resin sealing portion; a Si support bonding step of bonding a Si support to an electronic component layer; a dielectric film forming step of forming a dielectric film having a predetermined pattern on the Si base layer; and a cutting step of singulation with a dicing machine.

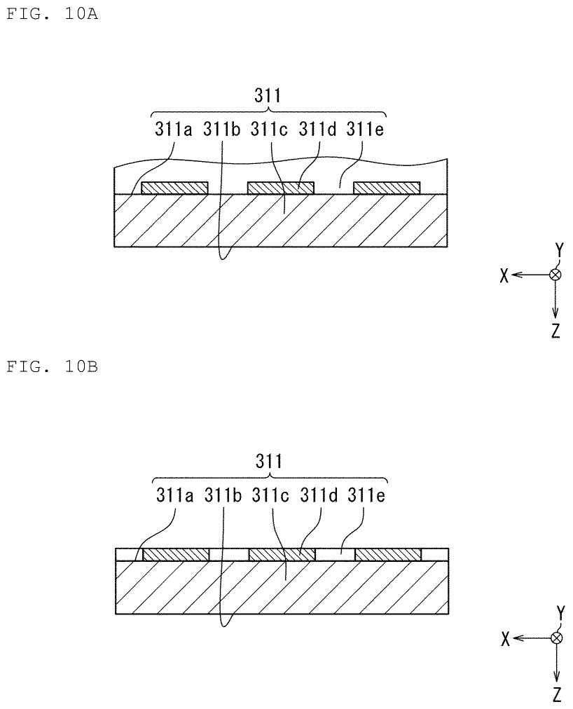

Specifically, an example of a method for manufacturing the composite component device 1 will be described with reference to FIGS. 10A to 10B and 4A to 4V. FIGS. 10A to 10B and FIGS. 4A to 4V are views for explaining a method for manufacturing the composite component device 1. The method for manufacturing the composite component device 1 according to the first embodiment includes: an insulating portion forming step; a Si base layer preparing step; an electronic component adhesive step; an electronic component sealing step; a resin sealing portion thinning step; a Si support bonding step; a Si base layer thinning step; a dielectric film forming step; a through hole forming step; a Si through-via forming step; a rewiring layer forming step; a laminating step; and a cutting step with a dicing machine. In this manufacturing method, there is made a mother aggregate in which the composite component devices 1 are integrated from the electronic component adhesive step to the laminating step. In addition, in this manufacturing method, the third composite component layer 300, the second composite component layer 200, and the first composite component layer 100 are made in this order.

### Insulating Portion Forming Step

In the insulating portion forming step, the first insulating portion 111e is formed between the first component electrodes 111d of the first electronic component 111. Specifically, in the resin layer forming step, a coating film containing a resin is formed, and is subjected to planarization processing to form the first insulating portion 111e. As illustrated in FIG. 10A, a solution containing a resin and a solvent is applied using a spin coating method to form a coating film. Herein, the lowest portion of the coating film is made higher than the highest portion of the first component electrode 111d. That is, the coating film is formed such that all of the plurality of first component electrodes 111d are fully buried in the coating film. The coating layer is dried to form the first insulating portion 111e. The first insulating portion 111e before the subsequent planarization processing preferably fully covers the first component electrode 111d.

In the planarization processing, as illustrated in FIG. 10B, for example, the surfaces of the first component electrode 111d and the first insulating portion 111e are ground and planarized using a surface planer and a grinder, and the first insulating portion 111e is formed between the first component electrodes 111d. Thereby, the top surface of the first component electrode 111d is exposed, and the top surfaces of the first component electrode 111d and the first insulating portion 111e are flush with each other.

### Si Base Layer Preparing Step

In the Si base layer preparing step, a third Si base layer 312 is prepared. Specifically, in the Si base layer preparing step, as illustrated in FIG. 4A, a Si wafer is prepared as the third Si base layer 312, a third electronic component adhesive layer 315 (strictly speaking, an adhesive coating film) is formed on the third Si base layer 312, and a third side wall portion 313 is disposed. This forms the third Si base layer 312 having a rectangular bottom surface portion in plain view and side wall portions disposed in a lattice shape so as to surround the rectangular bottom surface portion. One or more third electronic components 311 adheres to a recess (or indentation or cavity) surrounded by the bottom surface portion and the side wall portions in an electronic component adhesive step described later.

The adhesive coating film is formed on a second main surface 312b of the third Si base layer 312. This makes the third Si base layer 312 with the coating film formed. The coating method is, for example, spin coating. It is preferable to perform coating by controlling the thickness of the coating film so as to have the range from the thickness of the third component electrode 311d of one or more third electronic components 311 to 10 μm. The adhesive is, for example, a thermosetting resin. Such a thermosetting resin is, for example, a thermosetting resin containing a repeating unit derived from benzocyclobutene (BCB), and can be obtained by, for example, polymerizing 1,3-divinyl-1,1,3,3-tetramethyldisiloxane-bis-benzocyclobutene (DVS-bis-BCB). Examples of the commercially available product include “CYCLOTENE” manufactured by The Dow Chemical Company.

The shape of the Si wafer may be a flat cylindrical shape when viewed from above in plain view, but is not limited thereto. In the present description, flat means that the height (h) of the columnar shape is smaller than the outer diameter (diameter: 2r) (h/2r<1). When the shape of the Si wafer is a cylindrical shape, the thickness of the Si wafer is, for example, 775 μm (300 mm of diameter φ of Si wafer), 725 μm (φ200 mm), 675 μm (φ150 mm), and 525 μm (φ100 mm). The Si base layer preparing step may be performed before the insulating portion forming step. Both the third Si base layer 312 and the third side wall portion 313 substantially include Si.

### Electronic Component Adhesive Step

In the electronic component adhesive step, one or more third electronic components 311 adheres to the third Si base layer 312 such that the plurality of third component electrodes 311d of one or more third electronic components 311 are in contact with the bottom surface portion of the third Si base layer 312 having the lattice-shaped third side wall portions 313 with the third electronic component adhesive layer 315 interposed therebetween. Specifically, in the electronic component adhesive step, as illustrated in FIG. 4B, one or more third electronic components 311 are disposed (mounted) on (the bottom surface portion of) the third Si base layer 312 such that the third component electrode 311d and the third insulating portion 311e are in contact with (the bottom surface portion of) the third Si base layer 312 with the third electronic component adhesive layer 315 (strictly speaking, an adhesive coating film) interposed therebetween. Then, the adhesive coating film is cured to form the third electronic component adhesive layer 315. Thereby, one or more third electronic components 311 adheres onto the third Si base layer 312.

The third electronic component 311 is disposed on the coating film using an apparatus including a vacuum chamber. Specifically, an electronic component integrated wafer (a wafer in which a plurality of one or more third electronic components 311 are integrated) is bonded to the third Si base layer 312 (the third Si base layer 312 having the third side wall portion 313). Pressure is applied bidirectionally along the laminating direction of the third electronic component 311. Specifically, the third Si base layer 312 is set on a lower stage in the vacuum chamber in the apparatus. The third electronic component 311 is vacuum-sucked (or sucked under a reduced pressure) to the upper stage in the vacuum chamber such that the third component electrode 311d of the third electronic component 311 faces the coating film. For alignment between the third Si base layer 312 and the electronic component integrated wafer, for example, a recognition mark of the third Si base layer 312 is used. One or more third electronic components 311 are disposed on the coating film side of the third Si base layer 312. The pressure is applied bidirectionally along a direction in which the upper and lower stages face each other, and heating is performed.

The electronic component integrated wafer adheres onto the third Si base layer 312 such that the third component electrode 311d and the third insulating portion 311e face the third Si base layer 312 with the third electronic component adhesive layer 315 interposed therebetween.

### Electronic Component Sealing Step

In the electronic component sealing step, one or more third electronic components 311 are sealed with a resin to form a third resin sealing portion 314. Specifically, in the electronic component sealing step, as illustrated in FIG. 4C, a liquid resin is applied using a dispenser onto the third Si base layer 312 on which one or more third electronic components 311 are mounted. Thereafter, the applied liquid resin is molded using a compression molding apparatus. Thereafter, the liquid resin is cured using, for example, a hot air circulation oven. The heat treatment condition in curing is, for example, 150° C. for 1 hour. Thereby, the third resin sealing portion 314 is formed.

### Resin Sealing Portion Thinning Step

In the resin sealing portion thinning step, the third resin sealing portion 314 is thinned. In the resin sealing portion thinning step, specifically, as illustrated in FIG. 4D, the third resin sealing portion 314 is ground and thinned using a back grinder of a Si wafer. In the electronic component thinning step, the surface of the third resin sealing portion 314 on the second surface 311b side of the third electronic component 311 is ground. The grinding amount is preferably as large as possible. The thickness of the third resin sealing portion 314 after thinning is, for example, 50 to 150 μm.

In FIG. 4D showing an example of the resin sealing portion thinning step, the third resin sealing portion 314 of the third electronic component layer 310 is ground, but one or more third electronic components 311 may be further ground. However, the functional portion inside the third electronic component 311 is intended not to be damaged. The functional portion is, for example, a dielectric and an electrode in the case of a capacitor, and is a wiring in the case of an inductor.

### Si Support Bonding Step

In the Si support bonding step, as illustrated in FIG. 4E, the third Si support 340 is bonded to the third resin sealing portion 314. Specifically, the Si wafer described in the Si base layer preparing step is separately prepared as the third Si support 340. Then, the adhesive layer 350 (strictly speaking, an adhesive coating film) is formed on the third Si support 340 by the method described in the electronic component adhesive step. Thereafter, the third resin sealing portion 314 is bonded onto the third Si support 340 such that the ground surface of the third resin sealing portion 314 is in contact with the coating film, and is applied by pressure and heated. This cures the adhesive coating film to form the adhesive layer 350, and the third Si support 340 is disposed on the ground surface of the third resin sealing portion 314 with the adhesive layer 350 interposed therebetween. The purpose of providing the third Si support 340 is to prevent occurrence of adverse effects (more specifically, reduction in strength, and the like) due to a thinner layer in the manufacturing process than before in the subsequent Si base layer thinning step.

The third Si support 340 can be thinned before bonding as necessary from the viewpoint of improving processability. This is because a dielectric film is formed using semiconductor device equipment in a subsequent step. For example, when the thickness of the third electronic component 311 is 150 μm, a Si wafer (φ300 mm, typical thickness 775 μm) as the third Si support 340 is thinned to about 625 μm.

### Si Base Layer Thinning Step

The Si base layer thinning step thins the third Si base layer 312. Specifically, in the Si base layer thinning step, as illustrated in FIG. 4F, the third Si base layer 312 is ground in the same manner as in the resin sealing portion thinning step to thin the third Si base layer 312 and flatten the ground surface. In the Si base layer thinning step, the third Si base layer 312 is thinned while being supported by the third Si support 340, and thus the third Si base layer 312 can be thinned effectively. Thereby, the method for manufacturing the composite component device 1 according to the present embodiment can manufacture a composite component device 1 that is excellent as an electronic component module and is reduced in a height and size. The grinding amount is preferably as large as possible within a range in which the above adverse effects can be prevented and, for example, constant strength can be maintained. In consideration of variations in the flattening of the ground surface, the thickness of the third Si base layer 312 after thinning is preferably 3 μm or more.

### Dielectric Film Forming Step

In the dielectric film formation step, a dielectric film 320a having a predetermined pattern is formed on the third Si base layer 312, as illustrated in FIGS. 4G, 4H, and 4I. Herein, FIGS. 4G to 4I are enlarged views of a portion corresponding to the portion C in FIG. 4F. The same applies to FIGS. 4J to 4M. In addition, note that FIGS. 4G to 4M are views mainly related to the formation of the third Si through-via 317 and the third rewiring layer 320, and thus for convenience they are enlarged such that the third Si through-via 317, the third rewiring layer 320, and the areas where they are formed are largely occupied.

Specifically, a chemical vapor deposition (CVD) method such as plasma-enhanced chemical vapor deposition (PECVD) is used to form a dielectric film 320a (thickness 0.1 to 0.2 μm) on the entire surface of the third Si base layer 312, as illustrated in FIG. 4G. One or more layers of the dielectric film 320a may be formed. For example, when the four-layer dielectric film 320a is formed, SiO₂: 0.25 μm/Si₃N₄: 0.1 μm/SiO₂: 0.25 μm/Si₃N₄ 0.1 μm can be formed in this order from the third Si base layer 312 side. In addition, in the dielectric film forming step, the surface of the third Si base layer 312 can be cleaned before the dielectric film 320a is formed. The cleaning is performed by, for example, wet cleaning and oxygen plasma ashing.

Then, as illustrated in FIG. 4H and FIG. 4I, the dielectric film 320a is patterned using a photolithography method. A liquid resist is spin-coated to form a photoresist film 360 on the entire surface of the dielectric film 320a. The photoresist film 360 is exposed through a mask corresponding to a predetermined pattern. The exposed photoresist film 360 is developed. The dielectric film 320a of the photoresist film 360 is selectively removed by reactive ion etching (RIE). For example, when the above four-layer dielectric film 320a is formed, two layers on the front surface side of the dielectric film 320a (the surface side of the dielectric film 320a facing the third Si base layer 312) are selectively removed. Thereafter, the photoresist film 360 is peeled off. This causes the dielectric film 320a having a predetermined pattern to be formed on the third Si base layer 312. The dielectric film 320a also functions as an insulating film to electrically insulate two third Si through vias 317 illustrated in FIG. 4L, which will be described later. The first main surface 312a of the third Si base layer 312 may further have a mark layer. The mark layer can be detected by an infrared (IR) camera for alignment in a photolithography process.

### Through Hole Forming Step

In the through hole forming step, the through holes 312c and 315c are formed in the thinned third Si base layer 312 and third electronic component adhesive layer 315 to expose a part of the surface of the third component electrode 311d. Specifically, in the through hole forming step, the photoresist film 360 is formed on the entire surface. The photoresist film 360 is exposed through a mask corresponding to the pattern of the third Si through-via 317. The exposed photoresist film 360 is developed to form a photoresist film 360 having a predetermined pattern as illustrated in FIG. 4J. As illustrated in FIG. 4K, the third Si base layer 312 and the third electronic component adhesive layer 315 existing in the Z direction from a cavity 360a of the photoresist film 360 are selectively removed (etched). The etching is performed using, for example, RIE and laser irradiation. As a result, the through holes 312c and 315c are formed, and (a part of the upper surface of) the third component electrode 311d is exposed. Herein, the through hole 315c of the third electronic component adhesive layer 315 in the ZX section has a substantially elliptical shape. In the present description, the substantially elliptical shape includes not only a strict elliptical shape but also a similar elliptical shape in consideration of actual variations such as etching conditions and the like during manufacturing. This is because the material constituting the third electronic component adhesive layer 315 is more easily etched than the material constituting the third Si base layer 312. Thereby, the substantially elliptical extending portion 317b is formed in the subsequent Si through-via forming step. After the through holes 312c and 315c are formed, the photoresist film 360 is removed. The etching means is preferably RIE. The flatness of the upper surface of the third component electrode 311d to be exposed is improved by using RIE as etching means, and thus it is possible to form a favorable junction with the third Si through-via 317 to be formed later. This can further suppress a decrease in electrical connectivity.

### Si Through-Via Forming Step

In the Si through-via forming step, a Si through-via is formed in a through hole. Specifically, in the through hole forming step, as illustrated in FIG. 4L, the third Si through-via 317 is formed in the through holes 312c and 315c by electroplating. The third Si through-via 317 is formed in the through holes 312c and 315c by electroplating (more specifically, electrolytic Cu plating) using a dual damascene method (more specifically, a Cu dual damascene method). Thereby, the third electronic component layer 310 is formed.

### Rewiring Layer Forming Step

In the rewiring layer forming step, the third rewiring layer 320 is formed to make the third composite component layer 300. Specifically, in the rewiring layer forming step, as illustrated in FIG. 4M, the dielectric film 320a and the wiring 320b having a predetermined pattern are formed by the photolithography method and etching described above, and the third rewiring layer 320 is formed. In FIG. 4M, the dielectric film 320a formed in FIG. 4H and the wiring 320b formed in FIG. 4L are incorporated in the third rewiring layer 320. FIG. 4N shows a sectional view of the third composite component layer 300 encompassing FIG. 4M. FIG. 4M is an enlarged view of a portion C′ in FIG. 4N.

### Laminating Step

In the laminating step, another composite component layers (first and second composite component layers 100 and 200) are formed by the insulating portion forming step to the rewiring layer forming step described above, the electronic component layer through-vias 116 and 216 are formed in the another composite component layers, and the another composite component layers are laminated on the third composite component layer 300. In the present embodiment, the composite component layer is laminated twice.

Specifically, first, in the laminating step, the second composite component layer 200 is laminated on the third composite component layer 300. The second composite component layer 200 is formed by the insulating portion forming step to the rewiring layer forming step illustrated in FIGS. 4A to 4M. The second Si support 240 is removed from the second composite component layer 200 to which the second Si support 240 is bonded, and as illustrated in FIG. 4O, the second Si support 240 is newly bonded to the second rewiring layer 220 of the second composite component layer 200. As illustrated in FIG. 4P, the second composite component layer 200 illustrated in FIG. 4O is bonded to the third composite component layer 300 illustrated in FIG. 4N by the second interlayer adhesive layer 230. As illustrated in FIG. 4Q, the second Si support 240 is removed. As illustrated in FIG. 4R, the second electronic component layer through-via 216 is formed in the second composite component layer 200. The second electronic component layer through-via 216 can be formed by the same means as in the above described Si through-via step. Thereby, the second composite component layer 200 is laminated on the third composite component layer 300.

Then, the first composite component layer 100 is laminated. Similarly to the second composite component layer 200, the first composite component layer 100 is laminated on the second composite component layer 200 as illustrated in FIGS. 4A to 4P (refer to FIG. 4S). As illustrated in FIG. 4T, the first Si support 140 is removed. As illustrated in FIG. 4U, the first electronic component layer through-via 116 is formed in the first composite component layer 100. The first electronic component layer through-via 116 can be formed by the same means as in the above described Si through-via step. Thereby, the first composite component layer 100 is further laminated.

### Cutting Step with Dicing Machine

In the cutting step with a dicing machine, as illustrated in FIG. 4V, cutting is performed with a dicing machine to singulate the mother aggregate, and the third Si support 340 is removed. Thereby, the composite component device 1 is manufactured.

### Second Embodiment

### Configuration of Composite Component Device

The composite component device according to the second embodiment is different from the composite component device according to the first embodiment in not having the Si base layers 112, 212, and 312, the side wall portions 113, 213, and 313, and the Si through-vias 117, 217, and 317, having the metal layer 370, and in that the electronic component adhesive layers 115, 215, and 315 and the electronic component layer through-vias 116, 216, and 316 are different. This different configuration will be mainly described below. In the second embodiment, the same reference numerals as those of the first embodiment denote the same configurations as those of the first embodiment, and thus the description thereof will be basically omitted.

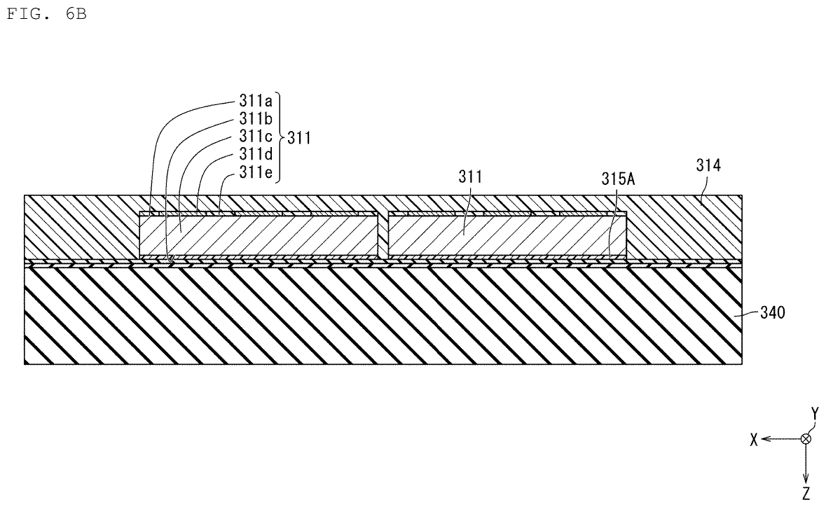

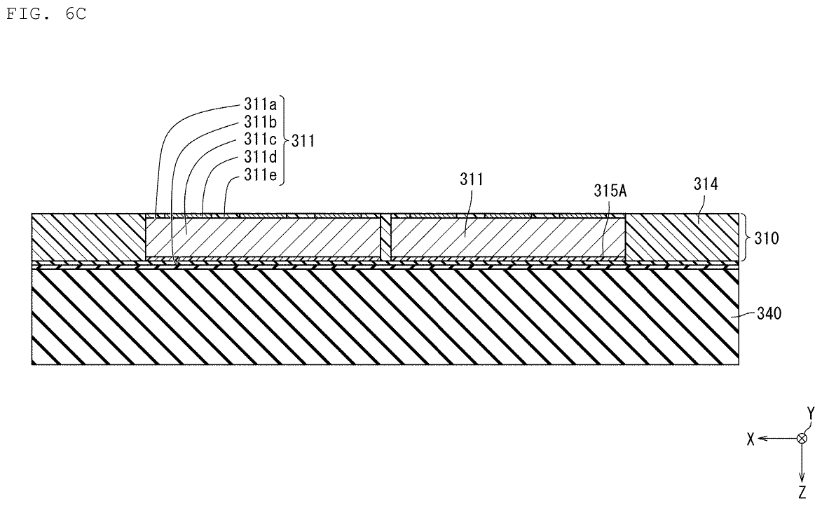

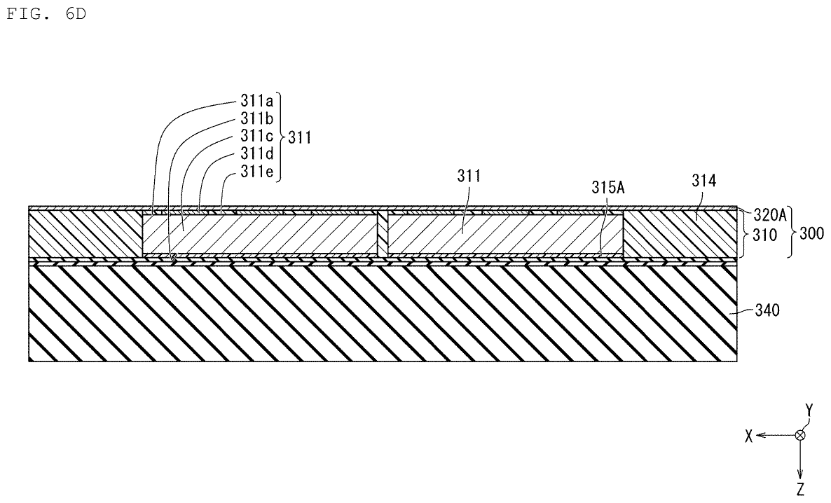

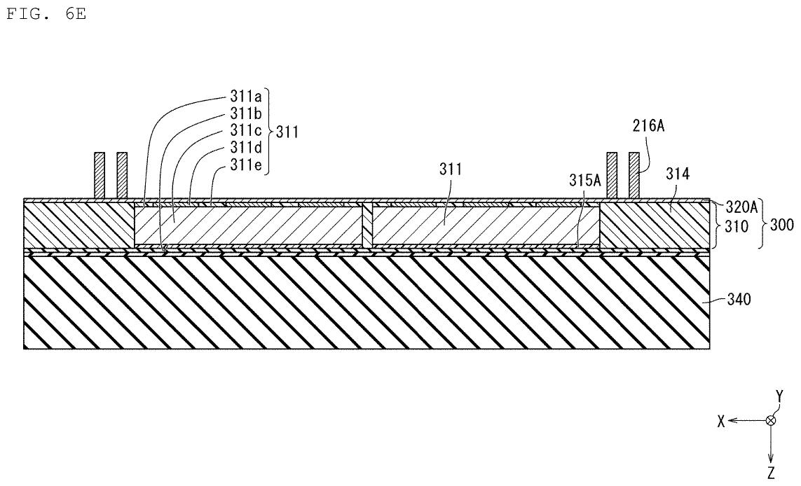

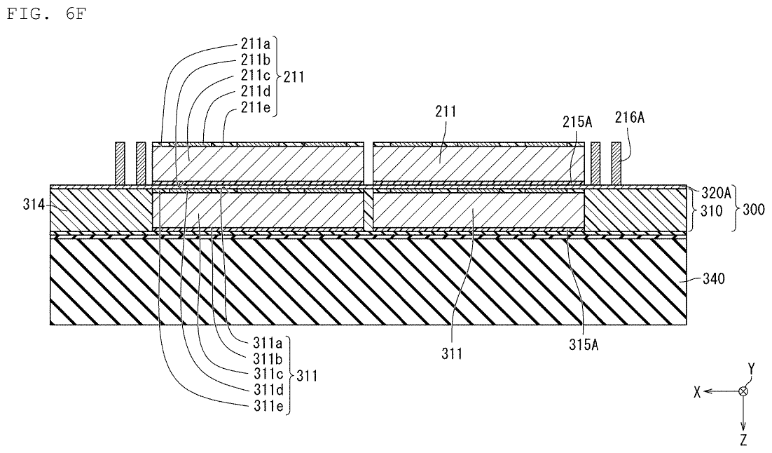

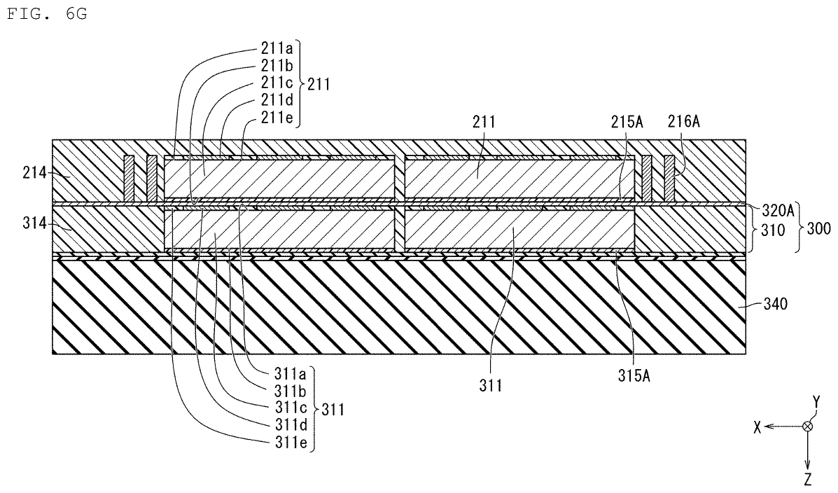

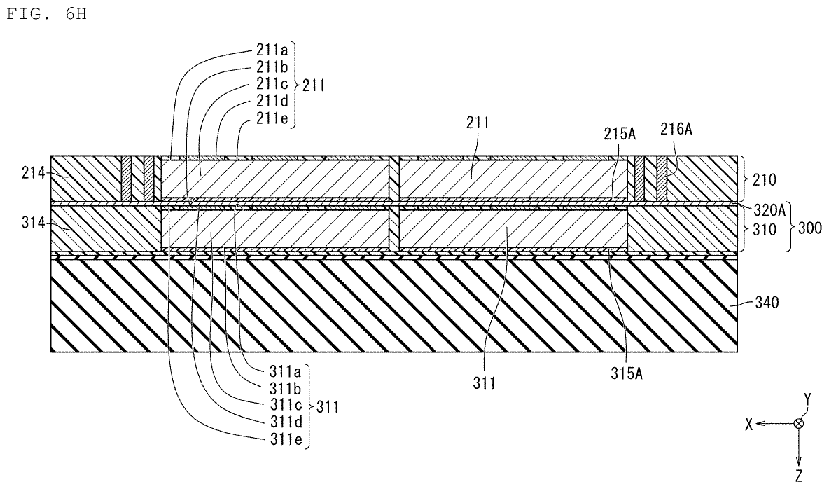

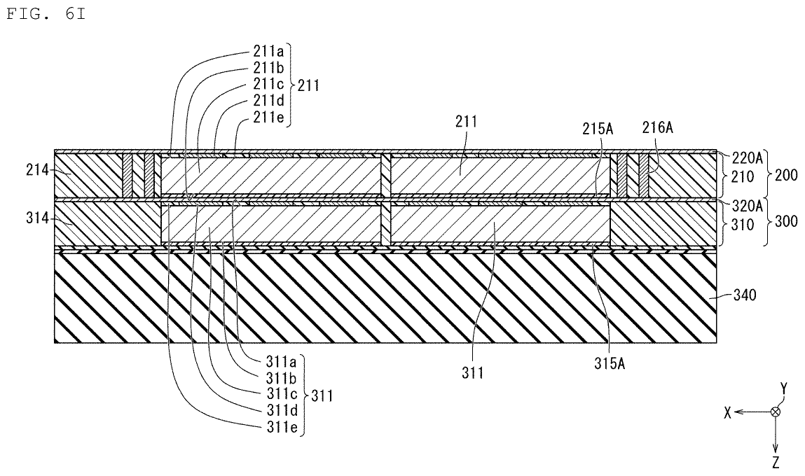

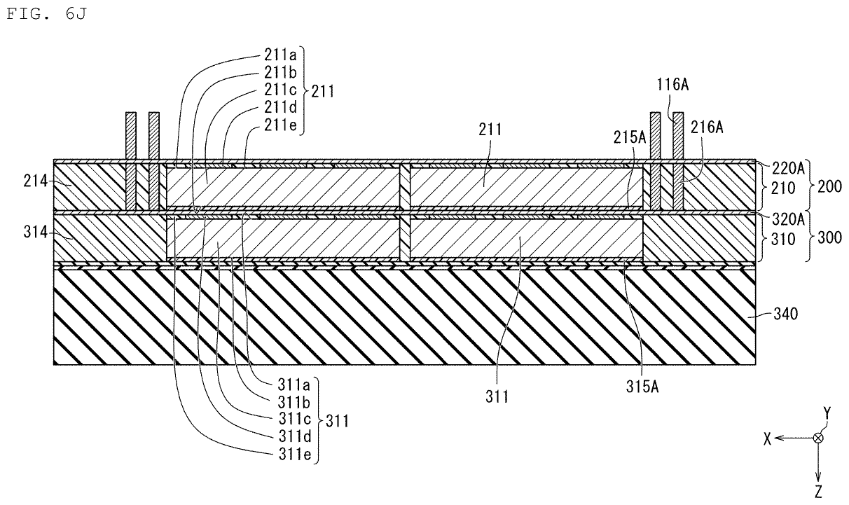

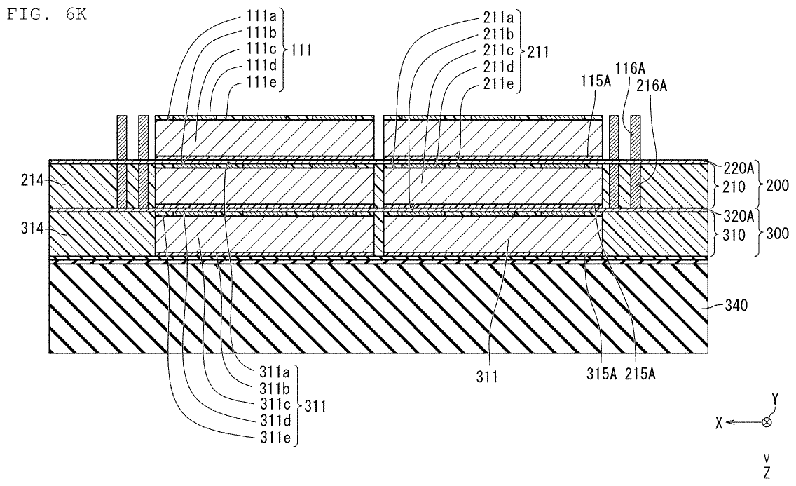

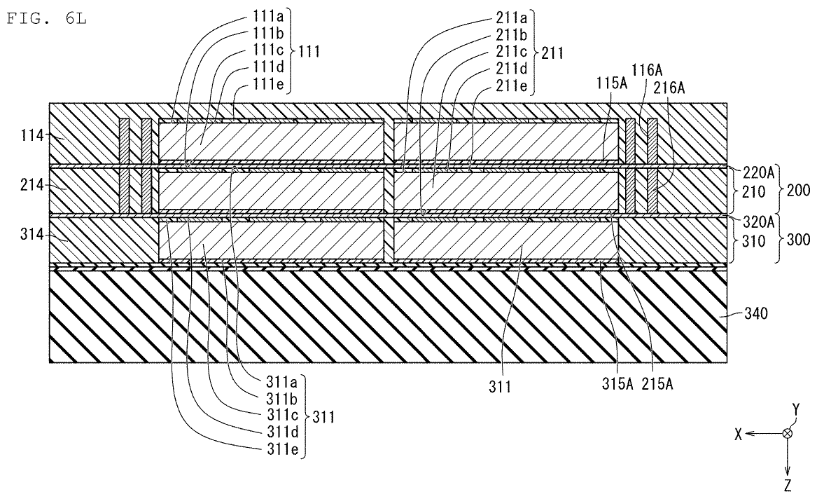

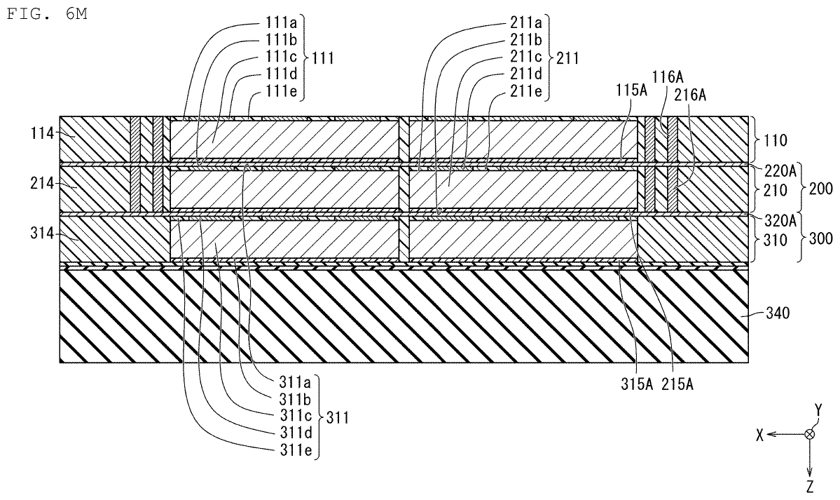

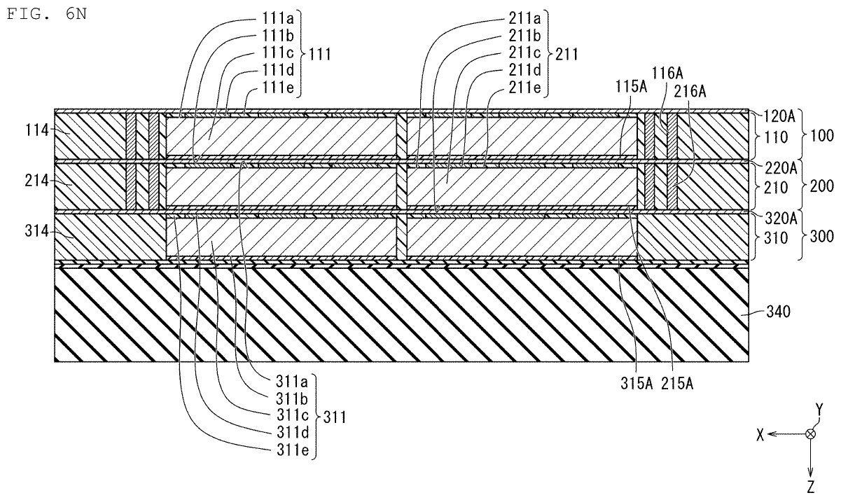

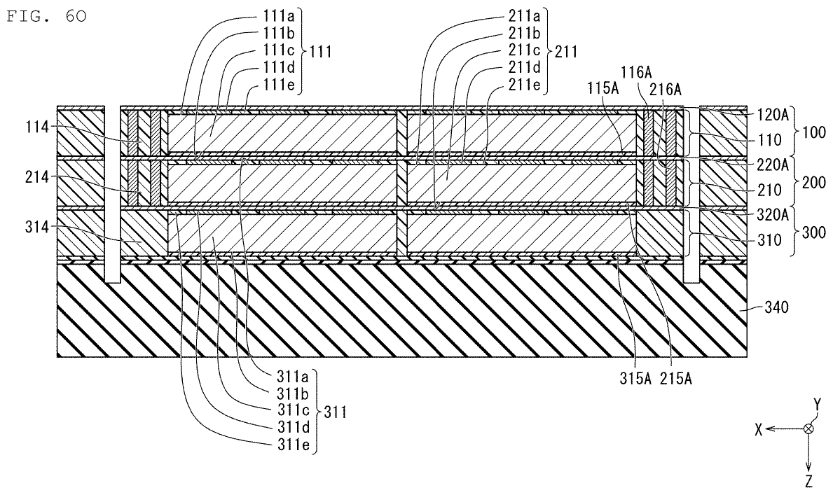

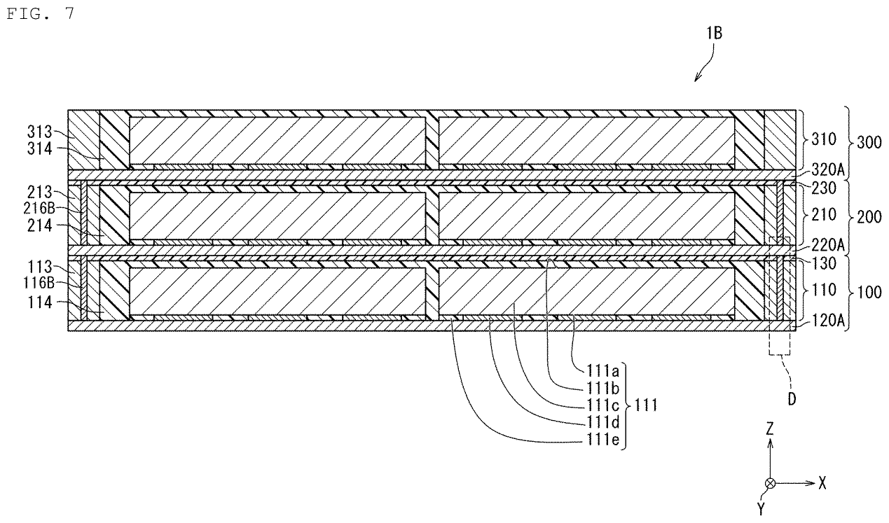

A configuration of the composite component device according to the second embodiment will be described with reference to FIGS. 5 and 6. FIG. 5 is a view schematically illustrating a section of the composite component device according to the second embodiment of the present disclosure. Similarly to the first embodiment, the configuration of the second and third composite component layers 200 and 300 is substantially the same as that of the first composite component layer 100, and thus the first composite component layer 100 will be mainly described below. However, matters different from the first composite component layer 100 may refer to the second and third composite component layers 200 and 300.

### Electronic Component layer

The first electronic component layer 110 has the first electronic component 111 and a first electronic component layer through-via 116A, and further has the first resin sealing portion 114 and a first electronic component adhesive layer 115A.

### Electronic Component

The first electronic component 111 is supported by a first rewiring layer 120A. The first component electrode 111d of the first electronic component 111 is directly electrically connected to (directly joined to) the first rewiring layer 120.

### Electronic Component Adhesive Layer

When the composite component layer is connected to a rewiring layer of another composite component layer, one or more electronic components disposed within the composite component layer adheres to the rewiring layer of the another composite component layer by the electronic component adhesive layer. More specifically, the first electronic component adhesive layer 115A causes the second surface 111b of the first electronic component 111 to adhere to the second rewiring layer 220A of the second composite component layer 200. The second electronic component adhesive layer 215A causes the second surface 211b of the second electronic component 211 to adhere to the third rewiring layer 320 of the third composite component layer 300. On the other hand, the third electronic component adhesive layer 315A causes the second surface 311b of the third electronic component 311 to adhere to the metal layer 370.

### Electronic Component Layer Through-Via

The first electronic component layer through-via 116A is a columnar wiring (more specifically, the Cu pillar). The sectional area of the first electronic component layer through-via 116A in the XY plane is larger than that of the first electronic component layer through-via 116 in the first embodiment. The sectional diameter of the first electronic component layer through-via 116A on the XY plane is, for example, 35 to 100 μm. The number of the first electronic component layer through-vias 116A is four in total in a sectional view, and two of them are disposed at each end of the first composite component layer 100.

The sectional area of the first electronic component layer through-via 116A in a plane perpendicular to the thickness direction of the composite component device 1A may increase from the second surface 111b of the first electronic component 111 toward the first surface 111a. That is, the shape (ZX sectional shape) of the first electronic component layer through-via 116A in the ZX section may be tapered with respect to the laminating direction of the composite component layers 100, 200, and 300. More specifically, the sectional area (XY sectional area) of the first electronic component layer through-via 116A on the XY plane may decrease from the second surface 111b toward the first surface 111a.

### Rewiring Layer

The first rewiring layer 120A is directly joined to the first component electrode 111d. When the first rewiring layer 120A is directly joined to the first component electrode 111d, the length of the via wiring between the first rewiring layer 120A and the first component electrode 111d can be further reduced, and thus the composite component device can be further reduced in size and height, and the electrical resistance of the via wiring can also be reduced.

The first rewiring layer 120A has a dielectric film substantially including an organic material (organic insulating material) and wiring (conductive wiring). Herein, the fact that the dielectric film substantially includes an organic material means that the dielectric film contains the organic material in a proportion of 99% by mass or more in the present description.

The dielectric film substantially includes an organic insulating material as an insulating material. Examples of the organic insulating material include epoxy resin, silicone resin, polyester, polypropylene, polyimide, acrylonitrile-butadiene-styrene (ABS) resin, acrylonitrile-styrene (AS) resin, methacrylic resin, polyamide, fluororesin, liquid crystal polymer, polybutylene terephthalate, and polycarbonate. When the insulating material constituting the dielectric film is an organic insulating material, the dielectric film is formed without using a method such as PECVD, for example, and thus the cost can be reduced as compared with the composite component device 1 according to the first embodiment. The line-and-space (L/S) of the first rewiring layer 120A including the dielectric film substantially including an inorganic material is, for example, 10 μm/10 μm. The thickness of the dielectric film is, for example, 1 to 20 μm.

### Metal Layer

The third composite component layer 300 has a metal layer 370. The metal layer 370 functions as an electromagnetic shield of the composite component device 1A.

### Method for Manufacturing Composite Component Device

An example of a method for manufacturing the composite component device 1A according to the second embodiment will be described.

The method for manufacturing the composite component device 1A according to the second embodiment includes, for example, an electronic component adhesive step of causing one or more electronic components to adhere to a Si support (Si support substrate) such that a second surface of the one or more electronic components is in contact with the Si support with an electronic component adhesive layer interposed therebetween; an electronic component sealing step of sealing one or more electronic components with a resin to form a resin sealing portion; a resin sealing portion thinning step of thinning the resin sealing portion to expose the entire surface of the component electrode; a rewiring layer forming step of forming a rewiring layer to make a composite component layer; and a laminating step of forming an electronic component layer through-via on the composite component layer, causing the one or more electronic components to adhere to the composite component layer such that a second surface of the one or more electronic components is in contact with the composite component layer with the electronic component adhesive layer interposed therebetween, sealing the one or more electronic components with a resin to form a resin sealing portion, thinning the resin sealing portion to expose the entire surface of the component electrode, forming a rewiring layer, and laminating another composite component layer on the composite component layer. The laminating step is performed at least once.

The method for manufacturing the composite component device 1A according to the second embodiment further includes an insulating portion forming step of forming an insulating portion; and a cutting step of singulation with a dicing machine.

Specifically, an example of a method for manufacturing the composite component device 1A will be described with reference to FIGS. 6A to 6O. FIGS. 6A to 6O are views for explaining a method for manufacturing the composite component device 1A. The method for manufacturing the composite component device 1A according to the second embodiment includes, in chronological order, an insulating portion forming step, an electronic component adhesive step, an electronic component sealing step, a resin sealing portion thinning step, a rewiring layer forming step, a laminating step, and a cutting step with a dicing machine. Among these steps, the insulating portion forming step (refer to FIGS. 10A and 10B), the electronic component sealing step (refer to FIG. 6B), and the cutting step with a dicing machine (refer to FIG. 6O) are substantially the same as the corresponding steps of the first embodiment, and thus are omitted.

### Electronic Component Adhesive Step

In the electronic component adhesive step, one or more third electronic components 311 adhere to the third Si support 340 such that the second surfaces 311b of the one or more third electronic components 311 are in contact with the third Si support 340 with the third electronic component adhesive layer 315A interposed therebetween. Specifically, in the electronic component adhesive step, as illustrated in FIG. 6A, the third electronic component adhesive layer 315A (strictly speaking, an adhesive coating film) is formed on the second surface 311b of the third electronic component 311 (in which the third insulating portion 311e is formed in the same manner as in the insulating portion forming step of the first embodiment), and one or more third electronic components 311 are disposed (mounted) on the third Si support 340 (strictly speaking, the third Si support 340 on which the metal layer 370 is disposed with the adhesive layer 350 interposed therebetween) with the coating film interposed therebetween. Then, the third electronic component adhesive layer 315A is cured. Thereby, one or more third electronic components 311 adheres onto the third Si support 340.

### Resin Sealing Portion Thinning Step

In the resin sealing portion thinning step, the third resin sealing portion 314 is thinned to expose the entire surface of the third component electrode 311d. Specifically, in the resin sealing portion thinning step, as illustrated in FIG. 6D, the third resin sealing portion 314 is ground and thinned using a back grinder of a Si wafer. Thereby, the entire surface of the third component electrode 311d is exposed. In the present step, a part of the component electrode 311d and the third insulating portion 311e may be ground.

### Rewiring Layer Forming Step

In the rewiring layer forming step, the third rewiring layer 320A is formed to make the third composite component layer 300. Specifically, in the rewiring layer forming step, as illustrated in FIG. 6C, a dielectric film and wiring having a predetermined pattern are formed using a photolithography method to form the third rewiring layer 320A. In the second embodiment, a relatively expensive apparatus such as PVCVD is not used for forming the dielectric film, and thus the cost can be reduced.

### Laminating Step

In the laminating step, a second electronic component layer through-via 216A is formed on the third composite component layer 300, one or more second electronic components 211 adheres to the third composite component layer 300 such that the second surfaces 211b of the one or more second electronic components 211 are in contact with the third composite component layer 300 with the second electronic component adhesive layer 215A interposed therebetween, the one or more second electronic components 211 are sealed with a resin to form a second resin sealing portion 214, the second resin sealing portion 214 is thinned to expose the entire surface of the second component electrode 311d, the second rewiring layer 220A is formed, and another composite component layers (first and second composite component layers 100 and 200) are laminated on the third composite component layer 300. The laminating step is performed twice.

Specifically, in the laminating step, first, the second composite component layer 200 is laminated on the third composite component layer 300. As illustrated in FIG. 6E, the second electronic component layer through-via 216A is formed on the third composite component layer 300. Specifically, a dry film resist (DFR) is laminated on (the entire surface of) the third rewiring layer 320A of the third composite component layer 300. A cavity is provided through the DFR by photolithography. The second electronic component layer through-via 216A is formed in the cavity by Cu via plating. The DER is peeled off. Thereby, the second electronic component layer through-via 216A is formed on the third composite component layer 300.

Similarly to the electronic component adhesive step, as illustrated in FIG. 6F, one or more second electronic components 211 adheres to the third composite component layer 300 such that the second surface 211b of one or more second electronic components 211 is in contact with the third composite component layer 215 with the second electronic component adhesive layer 300A interposed therebetween.

Similarly to the electronic component sealing step, as illustrated in FIG. 6G, one or more second electronic components 211 are sealed with a resin to form a second resin sealing portion 214. Similarly to the resin sealing portion thinning step, as illustrated in FIG. 6H, the second resin sealing portion 214 is thinned to expose the entire surfaces of the second component electrode 211d and the second insulating portion 211e. As illustrated in FIG. 6I, the second rewiring layer 220A is formed in the same manner as the rewiring layer forming step. Thereby, the second composite component layer 200 is laminated on the third composite component layer 300.

Then, the first composite component layer 100 is laminated on the second composite component layer 200. As illustrated in FIGS. 6J to 6N, the first composite component layer 100 is laminated on the second composite component layer 200 in the same manner as the formation of the second composite component layer 200 in the laminating step described above.

The composite component device 1A according to the second embodiment is manufactured through the cutting step with a dicing machine illustrated in FIG. 6O.

### Third Embodiment

### Configuration of Composite Component Device

The composite component device according to the third embodiment is different from the composite component device according to the first embodiment in not having the Si base layers 112, 212, and 312, the electronic component adhesive layers 115, 215, and 315, and the Si through-vias 117, 217, and 317, and in that the electronic component layer through-vias 116, 216, and 316 are different. This different configuration will be mainly described below. In the third embodiment, the same reference numerals as those of the first and second embodiments denote the same configurations as those of the first and second embodiments, respectively, and thus the description thereof will be generally omitted.

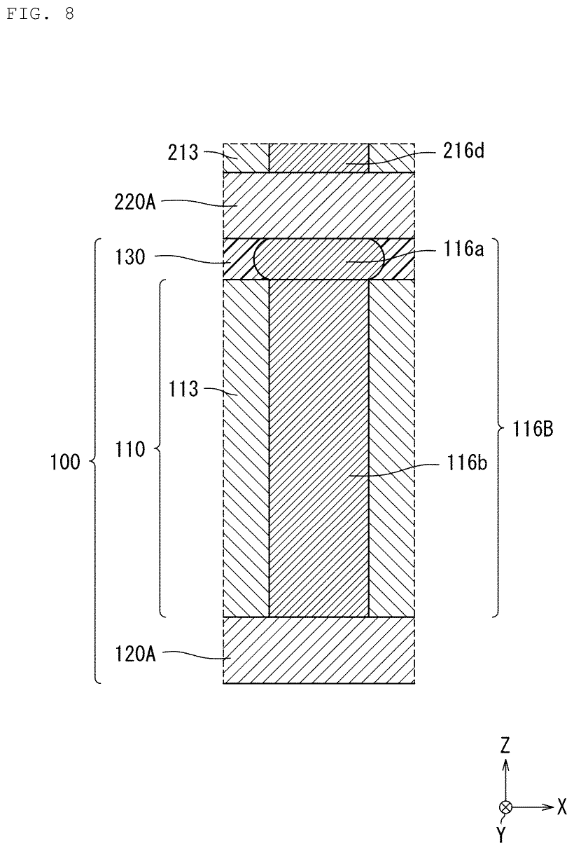

A configuration of the composite component device according to the third embodiment will be described with reference to FIGS. 7 and 8. FIG. 7 is a view schematically illustrating a section of the composite component device according to the third embodiment of the present disclosure. FIG. 8 is an enlarged view of a portion D of FIG. 7. Similarly to the first embodiment, the configuration of the second and third composite component layers 200 and 300 is substantially the same as that of the first composite component layer 100, and thus the first composite component layer 100 will be mainly described below. However, matters different from the first composite component layer 100 may refer to the second and third composite component layers 200 and 300. The first composite component layer 100 has the first electronic component layer 110 and the rewiring layer 120A provided on the first electronic component layer 110.

### Electronic Component Layer

The first electronic component layer 110 has the first electronic component 111 and the first electronic component layer through-via 116B, and further has the first side wall portion 113 and the first resin sealing portion 114.

### Electronic Component Layer Through-Via

The first electronic component layer through-via 116B is through the first side wall portion 113 of the first electronic component layer 110 in the Z direction and also is through the first interlayer adhesive layer 130. The first electronic component layer through-via 116B has an adhesive layer conductive via 116a through the first interlayer adhesive layer 130 and a sidewall through-via 116b through the first side wall portion 113.

### Method for Manufacturing Composite Component Device

An example of a method for manufacturing the composite component device 1B according to the third embodiment will be described.

The method for manufacturing the composite component device 1B according to the third embodiment includes: for example, an electronic component adhesive step of causing one or more electronic components to adhere to a Si base layer such that a plurality of component electrodes of one or more electronic components contact the bottom surface portion of the Si base layer having a lattice-shaped side wall portion with the electronic component adhesive layer interposed therebetween; an electronic component sealing step of sealing one or more electronic components with resin to form a resin sealing portion; a rewiring layer forming step of forming a rewiring layer to make a composite component layer; and a laminating step of forming another composite component layer by the electronic component adhesive step, the electronic component sealing step, and the rewiring layer forming step, forming an electronic component layer through-via on the side wall portion of the another composite component layer, and laminating the another composite component layer on the composite component layer. The laminating step is performed at least once.

A method for manufacturing the composite component device 1B according to the third embodiment further includes a Si base layer removing step of removing a Si base layer and an electronic component adhesive layer to exhibit the entire surface of a component electrode.

The method for manufacturing the composite component device 1B according to the third embodiment further includes a Si base layer preparing step of preparing a Si base layer; an insulating portion forming step of forming an insulating portion; a resin sealing portion thinning step of thinning a resin sealing portion; a Si support bonding step of bonding a Si support to an electronic component layer; and a cutting step of singulation with a dicing machine.

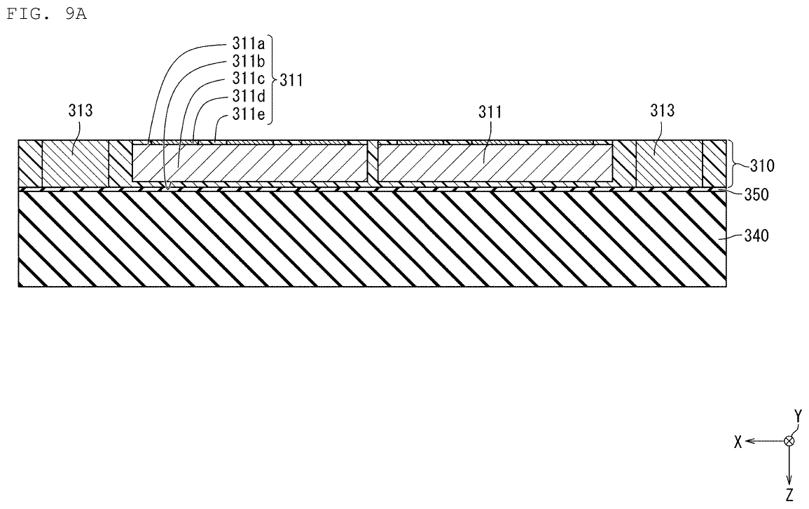

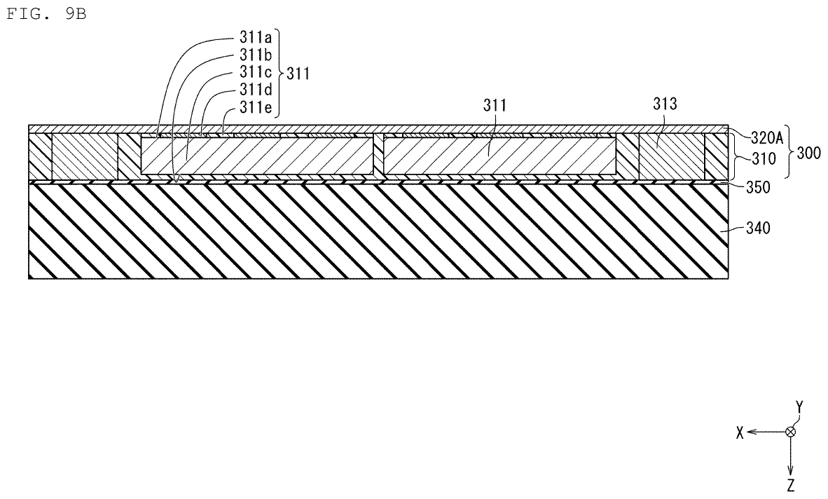

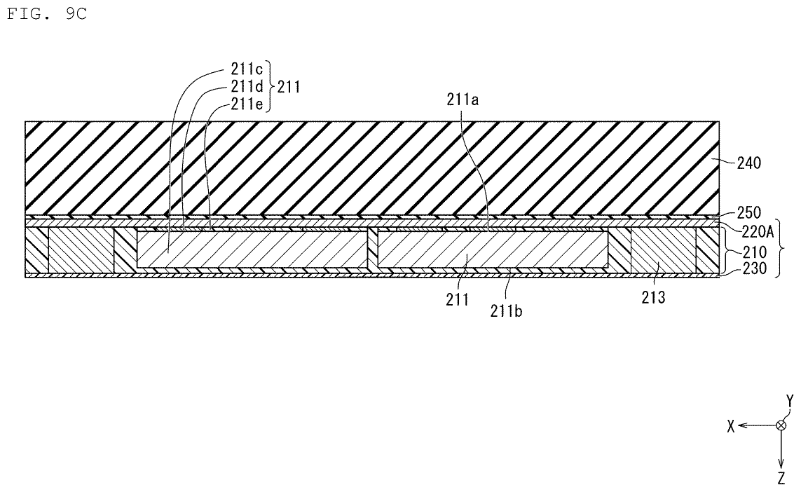

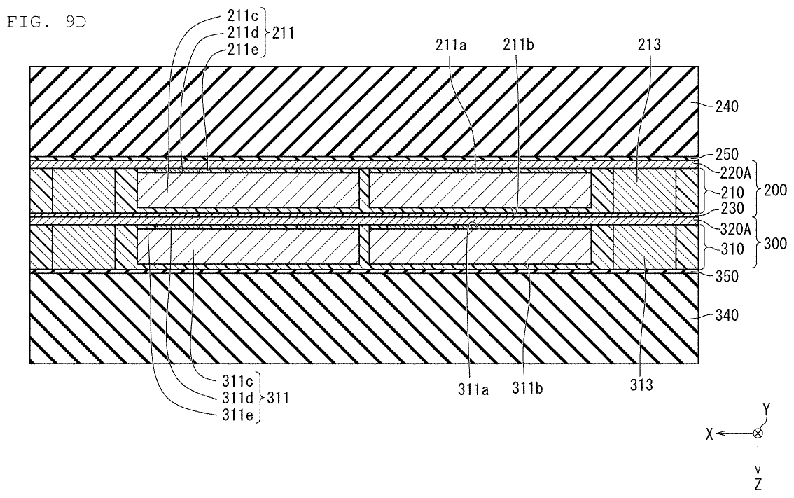

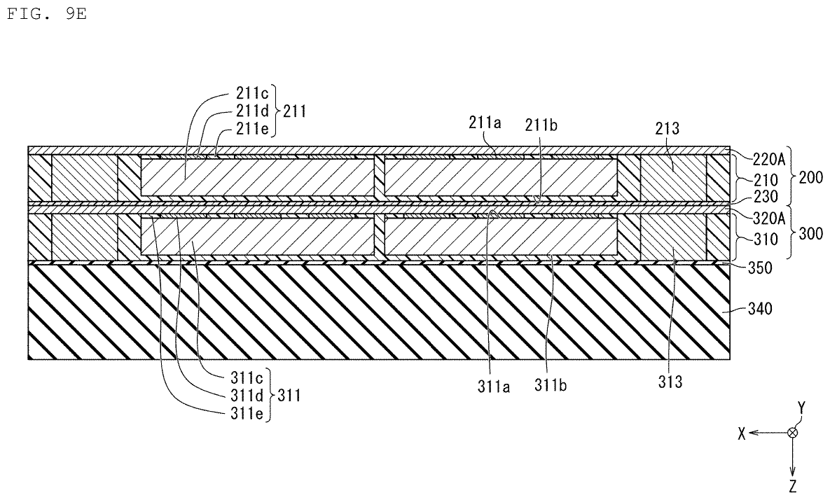

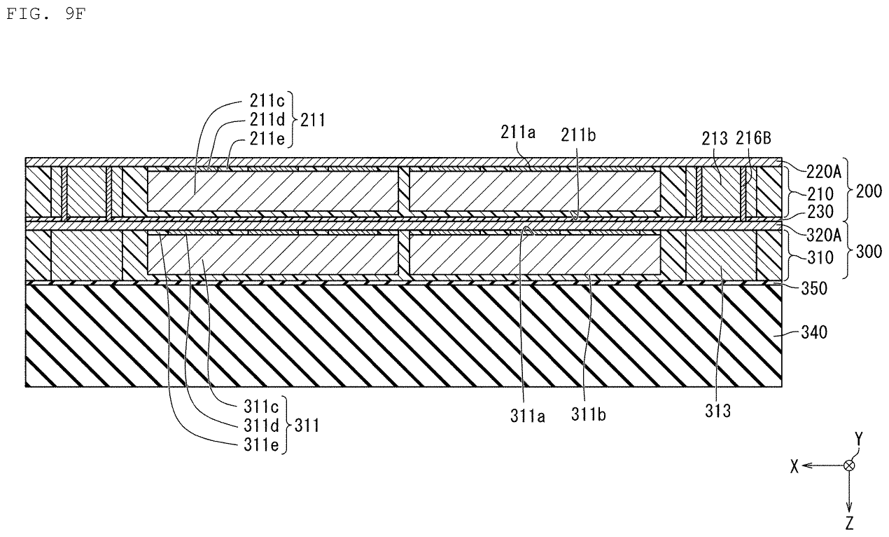

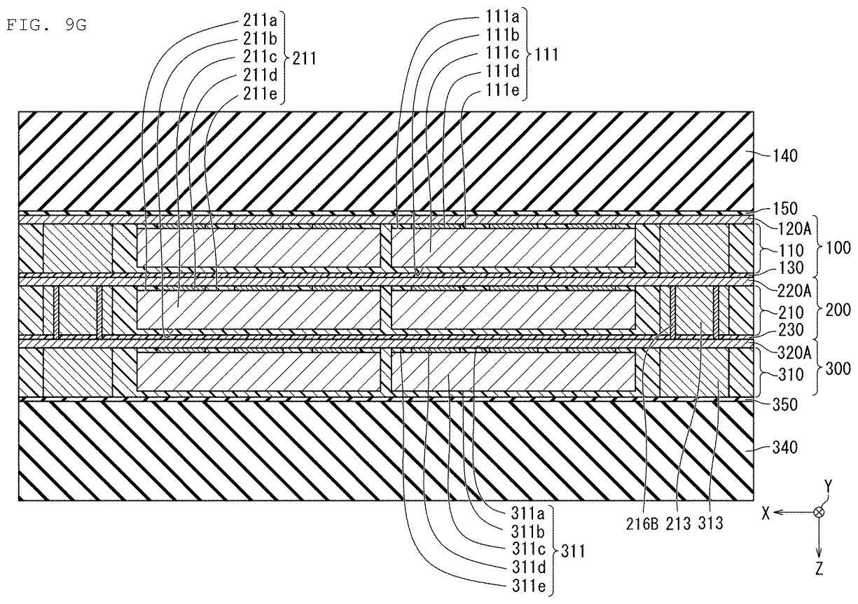

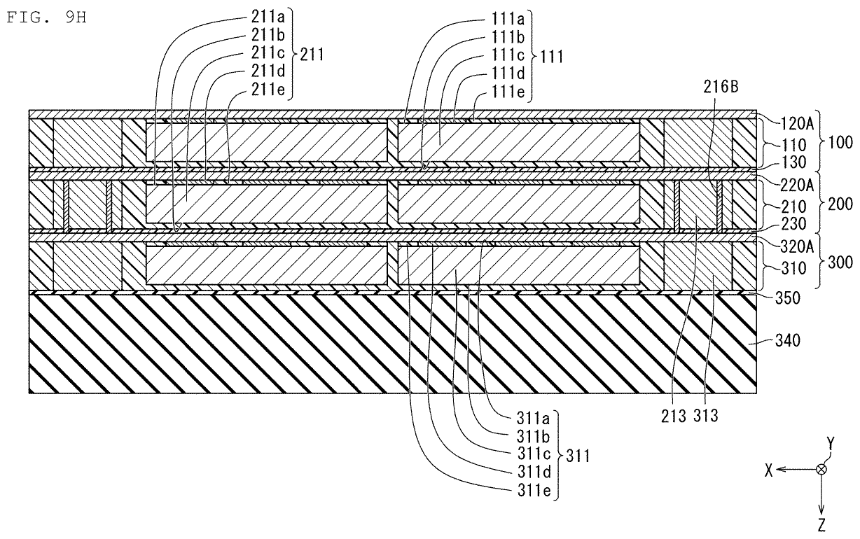

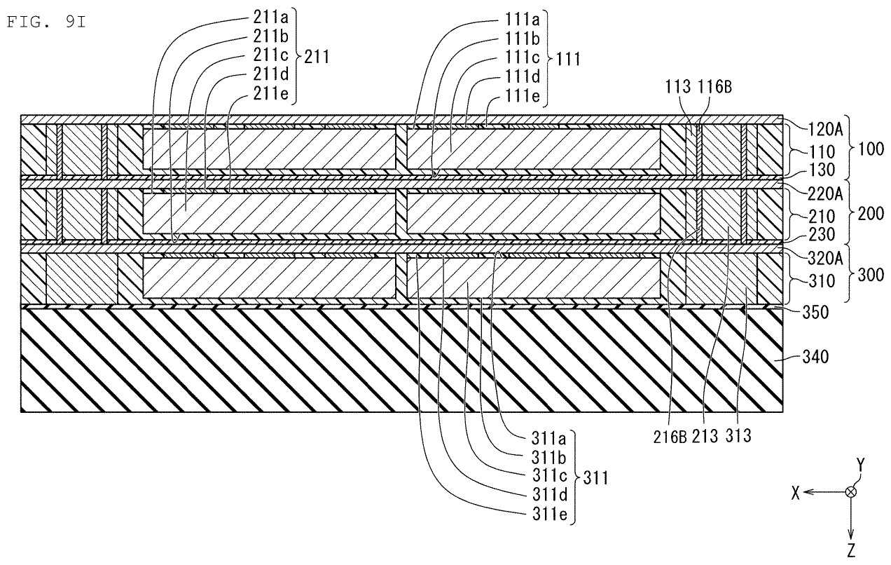

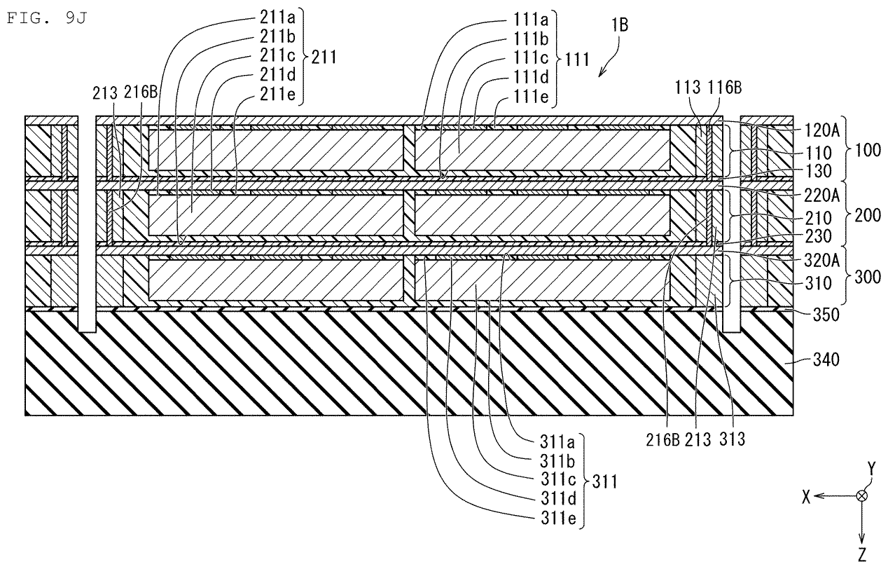

Specifically, an example of the method for manufacturing the composite component device 1B will be described with reference to FIGS. 9A to 9J. FIGS. 9A to 9J are views for explaining the method for manufacturing the composite component device 1B. The method for manufacturing the composite component device 1B according to the third embodiment includes: an insulating portion forming step; a Si base layer preparing step; an electronic component adhesive step; an electronic component sealing step; a resin sealing portion thinning step; a Si support bonding step; a Si base layer removing step; a rewiring layer forming step; a laminating step; and a cutting step with a dicing machine.

### Insulating Portion Forming Step to Si Support Bonding Step

As in the first embodiment, the insulating portion forming step to the Si support bonding step are performed (refer to FIGS. 4A to 4E).

### Si Base Layer Removing Step

In the Si base layer removing step, the third Si base layer 312 and the third electronic component adhesive layer 315 are removed to expose the entire surface of the third component electrode 111d. Specifically, in the Si base layer removing step, as illustrated in FIG. 9A, the third Si base layer 312 and the third electronic component adhesive layer 315 are removed using the same means as in the Si base layer thinning step in the first embodiment.

### Rewiring Layer Forming Step

In the rewiring layer forming step, the third rewiring layer 320A is formed. Specifically, in the rewiring layer forming step, as illustrated in FIG. 9B, the third rewiring layer 320A is formed using the same means as the rewiring layer forming step in the second embodiment. Thereby, the third composite component layer 300 is formed.

### Laminating Step

As illustrated in FIGS. 9C to 9I, in the laminating step, similarly to the laminating step of the first embodiment, another composite component layers (first and second composite component layers 100 and 200) are formed by the insulating portion forming step to the rewiring layer forming step, the electronic component layer through-vias 116B and 216B are formed in the another composite component layers, and the another composite component layers are laminated on the third composite component layer 300.

### Cutting Step With Dicing Machine

As in the first embodiment, the cutting step with a dicing machine is performed (refer to FIG. 9J). Thereby, the composite component device 1B is manufactured.

### Other Embodiments

The present disclosure is not limited to the above-described embodiments, and can be modified in design without departing from the gist of the present disclosure. In addition, the configurations of the first to third embodiments may be variously combined.

The first to third embodiments are the composite component devices 1, 1A, and 1B including three composite component layers, but are not limited thereto. For example, the composite component device may include two or four or more composite component layers. In such a case, the laminating step is performed once or three or more times in the method for manufacturing the composite component device. In the composite component device according to the present disclosure, the configurations of the respective composite component layers are substantially the same, and thus wiring design is less likely to be complicated, and electrical connection is likely to be performed between the composite component layers. Therefore, wiring can be easily formed if three or more composite component layers are laminated. For this reason, the number, types, and the like of electronic components incorporated in the circuit design are less likely to be limited, and the degree of freedom in design is high. A variety of circuit configurations become possible, and the application range becomes wider.

In the first to third embodiments, the composite component device has two electronic components of the same type in each composite component layer, which is not limited. For example, the composite component device may have different types of electronic components and may have one or three or more electronic components in each composite component layer. In addition, the composite component device may have a different number of electronic components in each composite component layer. For this reason, the number, types, and the like of electronic components incorporated in the circuit design are less likely to be limited, and the degree of freedom in design is high. A variety of circuit configurations become possible, and the application range becomes wider.

Aspects of the composite component device and the method for manufacturing the same according to the present disclosure are as follows.
<1> A composite component device including two or more composite component layers having an electronic component layer and a rewiring layer provided on the electronic component layer. The two or more composite component layers are laminated in a thickness direction such that the electronic component layer and the rewiring layer are alternately disposed, and the electronic component layer has one or more electronic components having: an electronic component main body having a first surface perpendicular to the thickness direction and a second surface opposed to the first surface; and a plurality of component electrodes disposed on the first surface. The component electrode of the one or more electronic components is electrically connected to the rewiring layer, and an electronic component layer in a composite component layer adjacent to the rewiring layer of another composite component layer of the two or more composite component layers further has an electronic component layer through-via electrically connected to the rewiring layer of the another composite component layer.
<2> The composite component device according to <1>, wherein the electronic component layer through-via substantially includes copper.
<3> The composite component device according to <1> or <2>, wherein the electronic component layer further has a resin sealing portion to seal the one or more electronic components.
<4> The composite component device according to any one of <1> to <3>,wherein all electronic components included in the composite component device are disposed in the two or more composite component layers such that a first surface thereof is located on a rewiring layer side with respect to a second surface.
<5> The composite component device according to any one of <1> to <4>, wherein the electronic component layer is disposed so as to surround the one or more electronic components and further has a side wall portion including the electronic component layer through-via.
<6> The composite component device according to any one of <1> to <5>, wherein the electronic component layer further has a Si base layer to support the one or more electronic components; and a Si through-via to be through the Si base layer to electrically connect the component electrode and the rewiring layer.
<7> The composite component device according to any one of <1> to <6>, wherein the rewiring layer has a dielectric film substantially including an inorganic material.
<8> The composite component device according to <5>, wherein the composite component layer adheres to the another composite component layer with an adhesive layer interposed therebetween, the electronic component layer through-via has a sidewall through-via to be through the side wall portion and a conductive via to be through the adhesive layer, the conductive via electrically connects the electronic component layer through-via and a rewiring layer of the another composite component layer, and a sectional area of the conductive via is larger than a sectional area of the sidewall through-via in a plane perpendicular to the thickness direction.
<9> The composite component device according to any one of <1> to <4>, wherein the rewiring layer is directly joined to the component electrode.
<10> The composite component device according to any one of <1> to <5> and <9>, wherein the rewiring layer has a dielectric film substantially including an organic material.
<11> The composite component device according to <10>, wherein a sectional area of the electronic component layer through-via in a plane perpendicular to the thickness direction increases from the second surface toward the first surface.
<12> A method for manufacturing the composite component device according to any one of <1> to <8>, wherein the electronic component layer of the composite component device is disposed so as to surround the one or more electronic components and further has a side wall portion through which the electronic component layer through-via is; and a resin sealing portion to integrate the one or more electronic components. The method includes an electronic component adhesive step of causing the one or more electronic components to adhere to the Si base layer such that a plurality of component electrodes of the one or more electronic components are in contact with a bottom surface portion of a Si base layer having a lattice-shaped side wall portion with an electronic component adhesive layer interposed therebetween; an electronic component sealing step of sealing the one or more electronic components with a resin to form a resin sealing portion; a rewiring layer forming step of forming the rewiring layer to make a composite component layer; and a laminating step of forming another composite component layer by the electronic component adhesive step, the electronic component sealing step, and the rewiring layer forming step and forming an electronic component layer through-via in the another composite component layer to laminate another composite component layer on the composite component layer. The laminating step is performed at least once.
<13> The method for manufacturing a composite component device according to <12>, the method further including a Si base layer thinning step of thinning the Si base layer; a through hole forming step of forming a through hole in the thinned Si base layer and the electronic component adhesive layer to expose a part of a surface of the component electrode; and a Si through-via forming step of forming a Si through-via in the through hole. The Si through-via is through the Si base layer and the electronic component adhesive layer, and electrically connects the rewiring layer and the component electrode of the electronic component, and a dielectric film of the rewiring layer substantially includes an inorganic material.
<14> The method for manufacturing a composite component device according to <12>, the method further including a Si base layer removing step of removing the Si base layer and the electronic component adhesive layer to expose an entire surface of the component electrode. The dielectric film of the rewiring layer substantially includes an organic material.
<15> A method for manufacturing the composite component device according to any one of <1> to <5> and <9>, wherein the electronic component layer of the composite component device further has a resin sealing portion to integrate the one or more electronic components, and the rewiring layer further has a dielectric film that is directly joined to the component electrode and that substantially includes an organic material. The method includes an electronic component adhesive step of causing the one or more electronic components to adhere to an Si support such that the second surface of the one or more electronic components is in contact with the Si support with an electronic component adhesive layer interposed therebetween; an electronic component sealing step of sealing the one or more electronic components with a resin to form a resin sealing portion; a resin sealing portion thinning step of thinning the resin sealing portion to expose an entire surface of the component electrode; a rewiring layer forming step of forming the rewiring layer to make a composite component layer; and a laminating step of forming the electronic component layer through-via on the composite component layer, causing the one or more electronic components to adhere to the composite component layer such that the second surface of the one or more electronic components is in contact with the composite component layer with an electronic component adhesive layer interposed therebetween, sealing the one or more electronic components with a resin to form a resin sealing portion, thinning the resin sealing portion to expose an entire surface of the component electrode, forming a rewiring layer, and laminating another composite component layer on the composite component layer. The laminating step is performed at least once.

The composite component device according to the present disclosure can be used by being mounted on various electronic devices

What is claimed is:

1. A composite component device comprising two or more composite component layers having an electronic component layer and a rewiring layer on the electronic component layer,
wherein
the two or more composite component layers are laminated in a thickness direction such that the electronic component layer and the rewiring layer are alternately disposed,
the electronic component layer has one or more electronic components having: an electronic component main body having a first surface perpendicular to the thickness direction and a second surface opposed to the first surface; and a plurality of component electrodes on the first surface,
the component electrode of the one or more electronic components is electrically connected to the rewiring layer,
an electronic component layer in a composite component layer adjacent to the rewiring layer of another composite component layer of the two or more composite component layers further has an electronic component layer through-via electrically connected to the rewiring layer of the another composite component layer,
the electronic component layer surrounds the one or more electronic components and further has a side wall portion including the electronic component layer through-via,
the composite component layer adheres to the another composite component layer with an adhesive layer interposed therebetween,
the electronic component layer through-via has a sidewall through-via through the side wall portion and a conductive via through the adhesive layer,
the conductive via electrically connects the electronic component layer through-via and a rewiring layer of the another composite component layer, and
a sectional area of the conductive via is larger than a sectional area of the sidewall through-via in a plane perpendicular to the thickness direction.

2. The composite component device according to claim 1, wherein
the electronic component layer through-via substantially includes copper.

3. The composite component device according to claim 1, wherein
the electronic component layer further has a resin sealing portion to seal the one or more electronic components.

4. The composite component device according to claim 1, wherein
all electronic components included in the composite component device are in the two or more composite component layers such that a first surface thereof is on a rewiring layer side with respect to a second surface.

5. The composite component device according to claim 1, wherein
the electronic component layer further has:
a Si base layer to support the one or more electronic components; and
a Si through-via through the Si base layer to electrically connect the component electrode and the rewiring layer.

6. The composite component device according to claim 1, wherein
the rewiring layer has a dielectric film substantially including an inorganic material.

7. A method for manufacturing the composite component device according to claim 1, wherein
the electronic component layer of the composite component device surrounds the one or more electronic components and further has:
a side wall portion including the electronic component layer through-via; and
a resin sealing portion to integrate the one or more electronic components,
the method comprising:
causing the one or more electronic components to adhere to a Si base layer of the electronic component such that a plurality of component electrodes of the one or more electronic components are in contact with a bottom surface portion of a Si base layer having a lattice-shaped side wall portion with an electronic component adhesive layer interposed therebetween;
sealing the one or more electronic components with a resin to form a resin sealing portion;
forming the rewiring layer to make a composite component layer; and
laminating by forming another composite component layer by performing the causing the one or more electronic components to adhere to the Si base layer, the sealing, and the forming of the rewiring layer, and forming an electronic component layer through-via in the another composite component layer to laminate another composite component layer on the composite component layer,
wherein the laminating is performed at least once.

8. The method for manufacturing a composite component device according to claim 7, the method further comprising:
thinning the Si base layer;
forming a through hole in the thinned Si base layer and the electronic component adhesive layer to expose a part of a surface of the component electrode; and
forming a Si through-via in the through hole,
wherein the Si through-via is through the Si base layer and the electronic component adhesive layer, and electrically connects the rewiring layer and the component electrode of the electronic component, and
a dielectric film of the rewiring layer substantially includes an inorganic material.

9. The composite component device according to claim 2, wherein
the electronic component layer further has a resin sealing portion to seal the one or more electronic components.

10. The composite component device according to claim 2, wherein
all electronic components included in the composite component device are in the two or more composite component layers such that a first surface thereof is on a rewiring layer side with respect to a second surface.

11. The composite component device according to claim 3, wherein
all electronic components included in the composite component device are in the two or more composite component layers such that a first surface thereof is on a rewiring layer side with respect to a second surface.

12. The composite component device according to claim 9, wherein
all electronic components included in the composite component device are in the two or more composite component layers such that a first surface thereof is on a rewiring layer side with respect to a second surface.

13. The composite component device according to claim 2, wherein
the electronic component layer further has:
a Si base layer to support the one or more electronic components; and
a Si through-via through the Si base layer to electrically connect the component electrode and the rewiring layer.

14. The composite component device according to claim 3, wherein
the electronic component layer further has:
a Si base layer to support the one or more electronic components; and
a Si through-via through the Si base layer to electrically connect the component electrode and the rewiring layer.

15. The composite component device according to claim 4, wherein
the electronic component layer further has:
a Si base layer to support the one or more electronic components; and
a Si through-via through the Si base layer to electrically connect the component electrode and the rewiring layer.

16. The composite component device according to claim 2, wherein
the rewiring layer has a dielectric film substantially including an inorganic material.

17. The composite component device according to claim 3, wherein
the rewiring layer has a dielectric film substantially including an inorganic material.

18. The composite component device according to claim 4, wherein
the rewiring layer has a dielectric film substantially including an inorganic material.

19. A method for manufacturing the composite component device according to claim 2, wherein
the electronic component layer of the composite component device surrounds the one or more electronic components and further has:
a side wall portion including the electronic component layer through-via; and
a resin sealing portion to integrate the one or more electronic components,
the method comprising:
causing the one or more electronic components to adhere to a Si base layer of the electronic component such that a plurality of component electrodes of the one or more electronic components are in contact with a bottom surface portion of the Si base layer having a lattice-shaped side wall portion with an electronic component adhesive layer interposed therebetween;
sealing the one or more electronic components with a resin to form a resin sealing portion;
forming the rewiring layer to make a composite component layer; and
laminating by forming another composite component layer by performing the causing the one or more electronic components to adhere to the Si base layer, the sealing, and the forming of the rewiring layer, and forming an electronic component layer through-via in the another composite component layer to laminate another composite component layer on the composite component layer,
wherein the laminating is performed at least once.

20. A method for manufacturing the composite component device according to claim 3, wherein
the electronic component layer of the composite component device surrounds the one or more electronic components and further has:
a side wall portion including the electronic component layer through-via; and
a resin sealing portion to integrate the one or more electronic components,
the method comprising:
causing the one or more electronic components to adhere to a Si base layer of the electronic component such that a plurality of component electrodes of the one or more electronic components are in contact with a bottom surface portion of the Si base layer having a lattice-shaped side wall portion with an electronic component adhesive layer interposed therebetween;
sealing the one or more electronic components with a resin to form a resin sealing portion;
forming the rewiring layer to make a composite component layer; and
laminating by forming another composite component layer by performing the causing the one or more electronic components to adhere to the Si base layer, the sealing, and the forming of the rewiring layer, and forming an electronic component layer through-via in the another composite component layer to laminate another composite component layer on the composite component layer,
wherein the laminating is performed at least once.
